(19) United States
(12) Patent Application Publication
(10) Pub. No.: US 2025/0057009 A1
(43) Pub. Date: Feb. 13, 2025

(54) DISPLAY APPARATUS

(71) Applicant: Samsung Display Co., Ltd., Yongin-si (KR)

(72) Inventors: Joongu Lee, Yongin-si (KR); Hwi Kim, Yongin-si (KR); Jungsun Park, Yongin-si (KR); Jihee Son, Yongin-si (KR); Seoulki Lee, Yongin-si (KR); Seungjun Lee, Yongin-si (KR); Areum Lee, Yongin-si (KR); Yeonhwa Lee, Yongin-si (KR)

(73) Assignee: Samsung Display Co., Ltd., Yongin-si (KR)

(21) Appl. No.: 18/597,742

(22) Filed: Mar. 6, 2024

(30) Foreign Application Priority Data
Aug. 8, 2023 (KR) 10-2023-0103695

(51) Int. Cl. H10K 59/80; H10K 59/122

(52) U.S. Cl. CPC H10K 59/80522; H10K 59/122

(57) ABSTRACT

A display apparatus includes a pixel area and an adjacent transmission area, first to third sub-pixel electrodes disposed on a substrate, disposed in the pixel area, and spaced apart from each other, a bank layer overlapping an edge of each of the first to third sub-pixel electrodes, first to third intermediate layers respectively disposed on the first to third sub-pixel electrodes and spaced apart from each other, first to third opposite electrodes respectively disposed on the first to third intermediate layers and spaced apart from each other, and an auxiliary electrode disposed on the bank layer. The first to third opposite electrodes respectively pass through edges of the first to third intermediate layers and electrically contact the auxiliary electrode.

### CROSS-REFERENCE TO RELATED APPLICATION(S)

This application claims priority to and benefits of Korean Patent Application No. 10-2023-0103695 under 35 U.S.C. § 119, filed on Aug. 8, 2023, in the Korean Intellectual Property Office, the entire contents of which are incorporated herein by reference.

### BACKGROUND

### 1. Technical Field

One or more embodiments relate to a display apparatus including a light-emitting diode.

### 2. Description of the Related Art

Display apparatuses display data visually. Display apparatuses may provide images by using light-emitting diodes. The usage of display apparatuses has diversified. Various attempts have been made to design transparent display apparatuses that allow objects behind the display apparatuses to be visible while images are being displayed.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

A display apparatus may include a pixel area in which a pixel displaying an image is disposed and a transmission area in which no pixel is disposed. As the transmittance in the transmission area increases, the transparency of the display apparatus may increase. Therefore, in order to implement a transparent display apparatus that allows objects behind the display apparatus to be visible while an image is being displayed, it is necessary to increase the transmittance in the transmission area.

Additional aspects will be set forth in part in the description which follows and, in part, will be apparent from the description, or may be learned by practice of the presented embodiments.

According to one or more embodiments, a display apparatus may include a pixel area and an adjacent transmission area; a first sub-pixel electrode, a second sub-pixel electrode, and a third sub-pixel electrode disposed on a substrate, disposed in the pixel area, and spaced apart from each other; a bank layer overlapping an edge of each of the first sub-pixel electrode, the second sub-pixel electrode, and the third sub-pixel electrode; a first intermediate layer, a second intermediate layer, and a third intermediate layer respectively disposed on the first sub-pixel electrode, the second sub-pixel electrode, and the third sub-pixel electrode and spaced apart from each other, a first opposite electrode, a second opposite electrode, and a third opposite electrode respectively disposed on the first intermediate layer, the second intermediate layer, and the third intermediate layer and spaced apart from each other; and an auxiliary electrode disposed on the bank layer, wherein the first opposite electrode, the second opposite electrode, and the third opposite electrode respectively pass through edges of the first intermediate layer, the second intermediate layer, and the third intermediate layer and electrically contact the auxiliary electrode.

In an embodiment, the auxiliary electrode may surround the pixel area and the transmission area in a plan view.

In an embodiment, the auxiliary electrode may be adjacent to the pixel area and the transmission area and may extend in a direction in a plan view.

In an embodiment, the auxiliary electrode may include a first portion surrounding the pixel area in a plan view.

In an embodiment, the first opposite electrode may pass through the edge of the first intermediate layer in a direction and may electrically contact the auxiliary electrode.

In an embodiment, a contact area of the first opposite electrode with the auxiliary electrode, a contact area of the second opposite electrode with the auxiliary electrode, and a contact area of the third opposite electrode with the auxiliary electrode may be different from each other.

In an embodiment, the auxiliary electrode may further include a second portion that is connected to the first portion, extending to the pixel area, and disposed between two of the first intermediate layer, the second intermediate layer, and the third intermediate layer, and at least one of the first opposite electrode, the second opposite electrode, and the third opposite electrode may be in contact with the second portion of the auxiliary electrode.

In an embodiment, the first opposite electrode may include a first portion and a second portion each overlapping the auxiliary electrode, and the first portion of the first opposite electrode and the second portion of the first opposite electrode may extend in different directions.

In an embodiment, the first opposite electrode may include a first portion and a second portion each overlapping the auxiliary electrode, and the first portion of the first opposite electrode and the second portion of the first opposite electrode may be disposed on opposite sides of the first opposite electrode.

In an embodiment, the first opposite electrode and the second opposite electrode may contact the second portion of the auxiliary electrode, and the first opposite electrode and the second opposite electrode may be in contact with each other on the second portion of the auxiliary electrode.

In an embodiment, the display apparatus may further include an insulating layer disposed between the substrate and the bank layer, and an encapsulation layer covering the opposite electrode and the auxiliary electrode, wherein the insulating layer and the encapsulation layer may directly contact the transmission area.

In an embodiment, an area of each of the first opposite electrode, the second opposite electrode, and the third opposite electrode may be greater than an area of each of the first intermediate layer, the second intermediate layer, and the third intermediate layer.

According to one or more embodiments, a display apparatus may include an auxiliary electrode disposed on a substrate and dividing the substrate into a plurality of pixel areas and a plurality of transmission areas; and a plurality of pixels disposed on the substrate corresponding to the plurality of pixel areas, respectively, wherein a first pixel among the plurality of pixels may include a first sub-pixel electrode, a second sub-pixel electrode, and a third sub-pixel electrode disposed in a first pixel area corresponding to the first pixel and spaced apart from each other; a first intermediate layer, a second intermediate layer, and a third intermediate layer respectively disposed on the first sub-pixel electrode, the second sub-pixel electrode, and the third sub-pixel electrode and spaced apart from each other, and a first opposite electrode, a second opposite electrode, and a third opposite electrode respectively disposed on the first intermediate layer, the second intermediate layer, and the third intermediate layer and spaced apart from each other, and the first opposite electrode, the second opposite electrode, and the third opposite electrode respectively pass through edges of the first intermediate layer, the second intermediate layer, and the third intermediate layer and electrically contact the auxiliary electrode, and the first opposite electrode, the second opposite electrode, and the third opposite electrode are respectively spaced apart from the plurality of transmission areas.

In an embodiment, the auxiliary electrode may have a substantially net structure surrounding each of the plurality of pixel areas and each of the plurality of transmission areas.

In an embodiment, a portion of the auxiliary electrode may extend to the first pixel area and may be disposed in an area between the first sub-pixel electrode, the second sub-pixel electrode, and the third sub-pixel electrode.

In an embodiment, at least one of the first opposite electrode, the second opposite electrode, and the third opposite electrode may pass through an edge of a corresponding one of the first intermediate layer, the second intermediate layer, and the third intermediate layer in two or more different directions and may contact the auxiliary electrode.

In an embodiment, an area of the first opposite electrode may be greater than an area of the first intermediate layer, and the first opposite electrode may directly contact the portion of the auxiliary electrode extending to the first pixel area.

In an embodiment, the display apparatus may further include an insulating layer disposed between the substrate and the first sub-pixel electrode, the second sub-pixel electrode, and the third sub-pixel electrode, and an encapsulation layer covering the first opposite electrode, the second opposite electrode, and the third opposite electrode, wherein the insulating layer and the encapsulation layer may directly contact each other in the plurality of transmission areas.

In an embodiment, a layer including a same material as a material of the first sub-pixel electrode, the second sub-pixel electrode, and the third sub-pixel electrode and the first opposite electrode, the second opposite electrode, and the third opposite electrode may not be present in at least one of the plurality of transmission areas.

In an embodiment, a second pixel adjacent to the first pixel may include a first sub-pixel electrode, a second sub-pixel electrode, and a third sub-pixel electrode disposed in a second pixel area corresponding to the second pixel and spaced apart from each other, a first intermediate layer, a second intermediate layer, and a third intermediate layer respectively disposed on the first sub-pixel electrode, the second sub-pixel electrode, and the third sub-pixel electrode disposed in the second pixel area and spaced apart from each other, and a first opposite electrode, a second opposite electrode, and a third opposite electrode respectively disposed on the first intermediate layer, the second intermediate layer, and the third intermediate layer disposed in the second pixel area and spaced apart from each other, and the first opposite electrode, the second opposite electrode, and the third opposite electrode corresponding to the second pixel area may be spaced apart from the first opposite electrode, the second opposite electrode, and the third opposite electrode corresponding to the first pixel area with the transmission area disposed between.

### BRIEF DESCRIPTION OF THE DRAWINGS

The above and other aspects, features, and advantages of embodiments of the disclosure will be more apparent from the following description taken in conjunction with the accompanying drawings, in which:

FIG. 1 is a schematic perspective view schematically illustrating a display apparatus according to an embodiment;

FIGS. 2A to 2E are schematic plan views schematically illustrating a portion of a display apparatus according to various embodiments;

FIGS. 3A and 3B are schematic cross-sectional views schematically illustrating a portion of a display apparatus according to various embodiments;

FIG. 4 is a schematic diagram of an equivalent circuit illustrating a sub-pixel of a display apparatus, according to an embodiment;

FIG. 5 is an enlarged schematic plan view illustrating a portion of a display apparatus according to an embodiment;

FIG. 6 is an enlarged schematic cross-sectional view illustrating a portion of a display apparatus according to an embodiment;

FIG. 7 is an enlarged schematic cross-sectional view illustrating a portion of a display apparatus according to an embodiment;

FIGS. 8A to 8C are enlarged schematic cross-sectional views illustrating a portion of a display apparatus according to various embodiments;

FIG. 9 is an enlarged schematic plan view illustrating a portion of a display apparatus according to an embodiment;

FIG. 10 is an enlarged schematic cross-sectional view illustrating a portion of a display apparatus according to an embodiment;

FIG. 11 is an enlarged schematic cross-sectional view illustrating a portion of a display apparatus according to an embodiment;

FIG. 12 is an enlarged schematic plan view illustrating a portion of a display apparatus according to an embodiment;

FIG. 13 is an enlarged schematic cross-sectional view illustrating a portion of a display apparatus according to an embodiment;

FIG. 14 is an enlarged schematic plan view illustrating a portion of a display apparatus according to an embodiment;

FIG. 15 is an enlarged schematic plan view illustrating a portion of a display apparatus according to an embodiment;

FIG. 16 is an enlarged schematic cross-sectional view illustrating a portion of a display apparatus according to an embodiment;

FIG. 17 is an enlarged schematic cross-sectional view illustrating a portion of a display apparatus according to an embodiment; and

FIGS. 18A and 18B are schematic cross-sectional views schematically illustrating states of a display apparatus manufacturing process according to various embodiments.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are described below, by referring to the figures, to explain aspects of the description.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

As the description allows for various changes and numerous embodiments, embodiments will be illustrated in the drawings and described in detail in the written description. Effects and features of the disclosure, and methods of achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings. When describing embodiments with reference to the accompanying drawings, the same or corresponding elements are denoted by the same reference numerals.

It will be understood that although the terms “first,” “second,” etc. may be used herein to describe various elements, these elements should not be limited by these terms. These terms are only used to distinguish one element from another. For example, a first element may be referred to as a second element, and similarly, a second element may be referred to as a first element without departing from the scope of the disclosure.

As used herein, the singular forms, “a,” “an,” and “the” are intended to include the plural forms as well, unless the context clearly indicates otherwise.

It will be further understood that the terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

It will be further understood that, when a layer, region, or element is referred to as being “on” another layer, region, or element, it may be directly or indirectly on the other layer, region, or element. For example, intervening layers, regions, or elements may be present.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

Also, sizes of elements in the drawings may be exaggerated or reduced for convenience of explanation. For example, because sizes and thicknesses of elements in the drawings are arbitrarily illustrated for convenience of explanation, the disclosure is not limited thereto.

When an embodiment may be implemented differently, a specific process order may be performed differently from the described order. For example, two consecutively described processes may be performed substantially at the same time or performed in an order opposite to the described order.

It will be further understood that when layers, regions, or elements are referred to as being connected or coupled to each other, they may be directly connected or coupled to each other or indirectly connected or coupled to each other with intervening layers, regions, or elements therebetween. For example, when layers, regions, or elements are referred to as being electrically connected to each other, they may be directly electrically connected to each other or indirectly electrically connected to each other with intervening layers, regions, or elements therebetween.

It will be understood that the terms “connected to” or “coupled to” may include a physical or electrical connection or coupling.

The x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

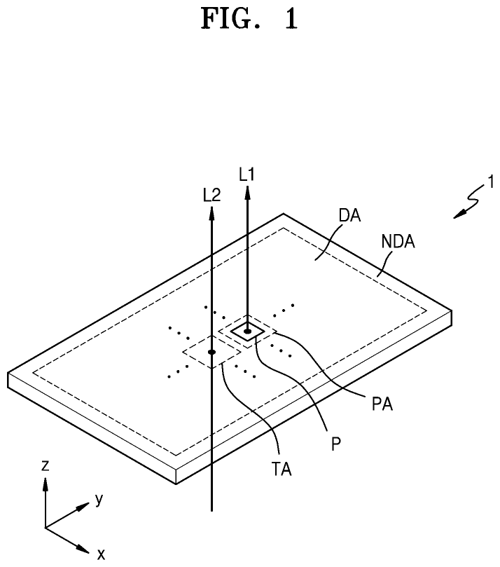

FIG. 1 is a schematic perspective view schematically illustrating a display apparatus 1 according to an embodiment.

Referring to FIG. 1, the display apparatus 1 may include a display area DA and a non-display area NDA outside the display area DA. The display area DA is an area in which an image is displayed through a pixel P arranged (or disposed) therein. The non-display area NDA is an area that is outside of the display area DA and may completely surround the display area DA. No image is displayed in the non-display area NDA. A driver or the like that supplies electrical signals or power to the display area DA may be arranged in the non-display area NDA. A pad, which is an area to which an electronic element or a printed circuit board may be electrically connected, may be arranged in the non-display area NDA.

In an embodiment, FIG. 1 illustrates that the display area DA has a polygonal shape (for example, a rectangular shape) in which the length of the display area DA in the ±x directions is less than the length of the display area DA in the ±y directions, but in an embodiment, the display area DA may have a polygonal shape (for example, a rectangular shape) in which the length of the display area DA in the ±y directions is less than the length of the display area DA in the ±x directions. Although FIG. 1 illustrates that the display area DA has a substantially rectangular shape, the disclosure is not limited thereto. In an embodiment, the display area DA may have various shapes, such as an N-gonal shape (where N is a natural number greater than or equal to 3), a circular shape, or an elliptical shape. FIG. 1 illustrates that corner portions of the display area DA include vertices at which straight lines meet each other, but in an embodiment, corner portions of the display area DA may have a round polygonal shape.

The display area DA may include a pixel area PA and a transmission area TA.

A corresponding pixel P may be arranged in the pixel area PA Pixel areas PA and pixels P may be provided. Each of the pixels P may provide a selectable image by emitting light L1.

The transmission area TA may be arranged adjacent to the pixel area PA and may transmit light. Light L2 incident on one surface (or a surface) of the display apparatus 1 in the transmission area TA may pass through the display apparatus 1 and travel to an opposite surface of the display apparatus 1. For example, the light L2 incident on the −z direction surface of the display apparatus 1 in the +z direction in the transmission area TA may pass through the display apparatus 1 and exit from the +z direction surface of the display apparatus 1. Transmission areas TA may be provided.

Accordingly, the display apparatus 1 may provide an image by using the light emitted from the pixel P and may also display an image incident from the rear (for example, the −z direction) of the display apparatus 1 by transmitting the light L2 incident on the transmission area TA. In other words, the display apparatus 1 may be a transparent display apparatus capable of displaying both the image provided by the display apparatus 1 and the image from the rear (for example, the −z direction) of the display apparatus 1.

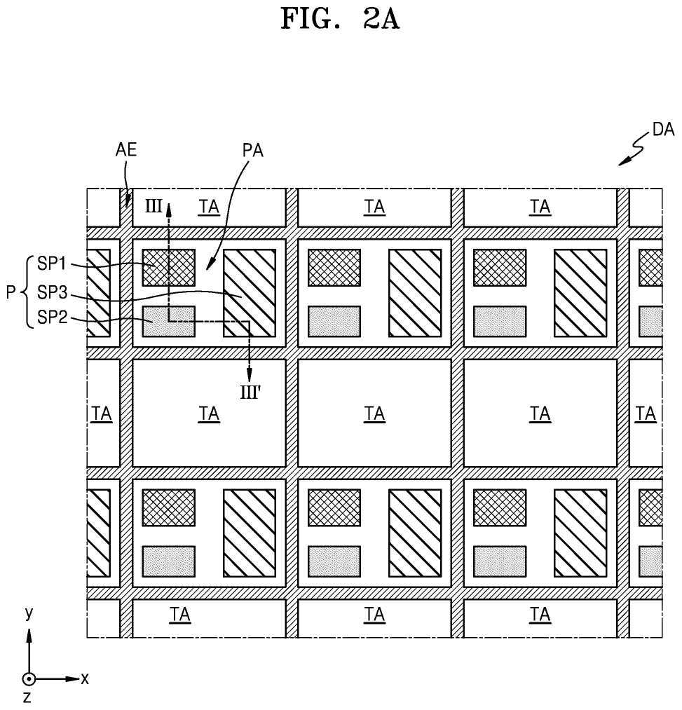

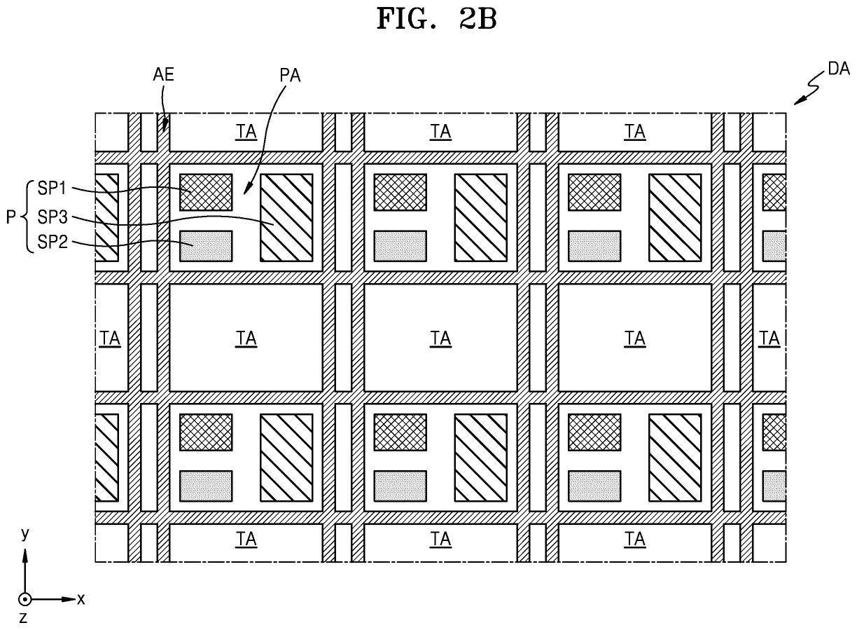

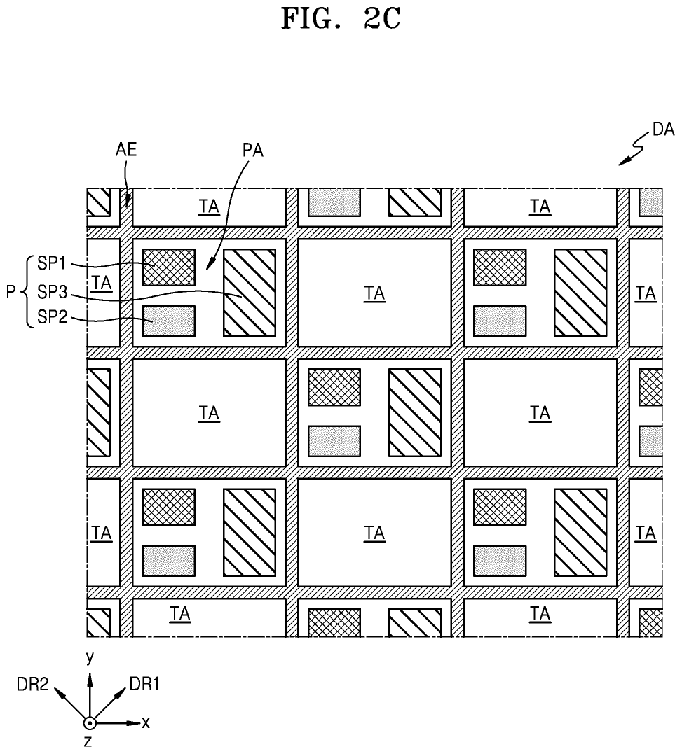

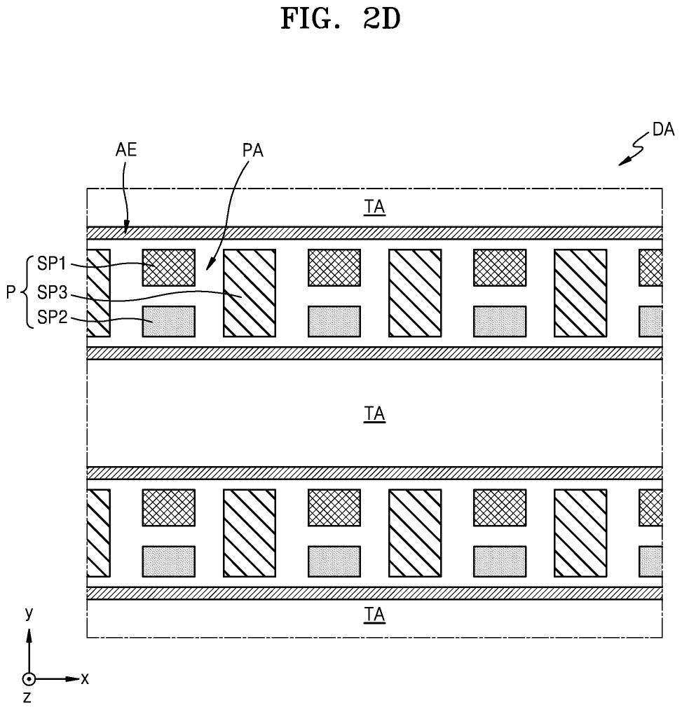

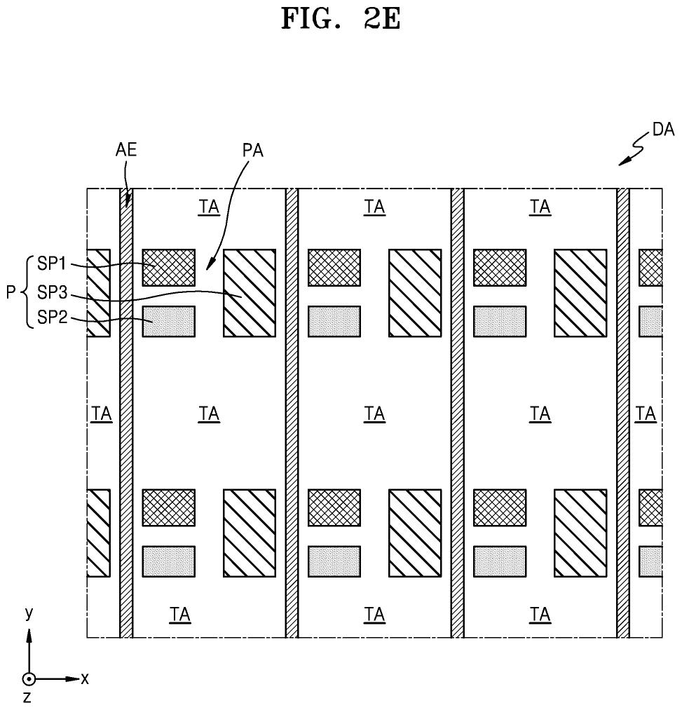

FIGS. 2A to 2E are schematic plan views schematically illustrating a portion of a display apparatus according to various embodiments.

Referring to FIG. 2A, a display area DA may include pixel areas PA and transmission areas TA.

Pixels P may be arranged in the pixel areas PA. FIG. 2A illustrates that one pixel P is arranged in one pixel area PA. However, in an embodiment, pixels P may be arranged in one pixel area PA. (see FIG. 2D)

The pixels P may be arranged in one direction (or a direction). For example, the pixels P may be spaced apart from each other in the ±x directions. The pixels P spaced apart from each other in the ±x directions may form one row. By way of example, it may be understood that the pixel areas PA spaced apart from each other in the ±x directions form one row.

The transmission areas TA may be arranged in one direction. For example, the transmission areas TA may be spaced apart from each other in the ±x directions. The transmission areas TA spaced apart from each other in the ±x directions may form one row.

The row of the transmission areas TA may be disposed above and/or below the row of the pixels P (or the row of the pixel areas PA) (or in the ±y directions). The row of the pixels P (or the row of the pixel areas PA) may be disposed above and/or below the row of the transmission areas TA (or in the ±y directions).

In other words, the row constituted by the pixels P (or the row constituted by the pixel areas P) arranged in the ±x directions and the row constituted by the transmission areas TA arranged in the ±x directions may be alternately arranged in the ±y directions.

As another example, when viewed based on the ±y directions, the pixel areas PA and the transmission areas TA may be alternately arranged in the ±y directions to make the row, and it may be understood that the corresponding columns are arranged in the ±x directions.

One pixel P may include sub-pixels. For example, the pixel P may include first to third sub-pixels SP1, SP2, and SP3. The first to third sub-pixels SP1, SP2, and SP3 may be arranged in the same pixel area PA.

The first to third sub-pixels SP1, SP2, and SP3 may be spaced apart from each other in the same pixel area PA. For example, the third sub-pixel SP3 may be arranged in the right region (or the +x side region) of one pixel area PA, the first sub-pixel SP1 may be arranged in the upper left region (or the −x and +y side region), and the second sub-pixel SP2 may be arranged in the lower left region (or the −x and −y side region).

The areas of the first to third sub-pixels SP1, SP2, and SP3 may be different from each other. For example, the area of the first sub-pixel SP1 may be greater than the area of the second sub-pixel SP2, and the area of the third sub-pixel SP3 may be greater than the area of the first sub-pixel SP1.

The first to third sub-pixels SP1, SP2, and SP3 may emit light of different colors. For example, the first sub-pixel SP1 may emit red light. The second sub-pixel SP2 may emit green light. The third sub-pixel SP3 may emit blue light. The pixel P may provide light of an arbitrary color (for example, the light L1 illustrated in FIG. 1) according to a combination of the intensities of light emitted from the first to third sub-pixels SP1, SP2, and SP3.

In an embodiment, the disclosure is not limited to the areas and arrangements of the first to third sub-pixels SP1, SP2, and SP3 and the colors of pieces of light emitted from the first to third sub-pixels SP1, SP2, and SP3. The areas and arrangements of the first to third sub-pixels SP1, SP2, and SP3 and the colors of pieces of light emitted from the first to third sub-pixels SP1, SP2, and SP3 may be variously changed.

Auxiliary electrodes AE may be between the pixel areas PA and the transmission areas TA. The auxiliary electrode AE may extend in the ±x directions and/or the ±y directions. For example, a portion of the auxiliary electrode AE may extend between the pixel area PA and the transmission area TA adjacent to each other. In an embodiment, the auxiliary electrode AE may extend in the ±x directions and the ±y directions and surround the pixel area PA and the transmission area TA.

In other words, the auxiliary electrode AE may have a substantially net structure, and the pixel area PA or the transmission area TA may be arranged in each hole of the net structure of the auxiliary electrode AE. By way of example, it may be understood that the auxiliary electrode AE has a net structure and divides the display area DA into the pixel areas PA and the transmission areas TA.

In an embodiment, the auxiliary electrode AE surrounding one pixel area PA and the auxiliary electrode AE surrounding the adjacent pixel area PA may share a portion with each other. For example, the right portion (or the +x direction portion) of the auxiliary electrode AE surrounding one pixel area PA may be substantially the same as the left portion (or the −x direction portion) of the auxiliary electrode AE surrounding the pixel area PA arranged on the right (or the +x direction).

In an embodiment, the auxiliary electrode AE surrounding one pixel area PA and the auxiliary electrode AE surrounding the adjacent transmission area TA may share a portion with each other. For example, the lower portion (or the −y direction portion) of the auxiliary electrode AE surrounding one pixel area PA may be substantially the same as the upper portion (or the +y direction portion) of the auxiliary electrode AE surrounding the transmission area TA arranged below (or the −y direction).

Referring to FIG. 2B, the auxiliary electrode AE may further include an additional structure extending in the ±y directions, compared to the embodiment illustrated in FIG. 2A.

In an embodiment, the auxiliary electrode AE surrounding one pixel area PA and the auxiliary electrode AE surrounding the adjacent pixel area PA may not share a portion with each other. For example, the right portion (or the +x direction portion) of the auxiliary electrode AE surrounding one pixel area PA may be separate from the left portion (or the −x direction portion) of the auxiliary electrode AE surrounding the pixel area PA arranged on the right (or the +x direction).

In other words, two portions of the auxiliary electrode AE extending in the ±y directions may be spaced apart from each other between two adjacent pixel areas PA. Accordingly, the two portions of the auxiliary electrode AE and a space defined between the two portions of the auxiliary electrode AE and having a relatively small size, compared to the pixel area PA, may be between the two adjacent pixel areas PA.

The structure of the auxiliary electrode AE and the space may prevent opposite electrodes arranged in the two adjacent pixel areas PA from coming into contact with each other in case that the opposite electrodes to be described below are arranged in the pixel area PA and extend onto the auxiliary electrode AE. Because the area of the auxiliary electrode AE increases, an effect of reducing electrical resistance within the auxiliary electrode AE may be obtained.

Referring to FIG. 2C, the arrangement of pixel areas PA and transmission areas TA may be different from that of the embodiment illustrated in FIG. 2A.

In an embodiment, the pixel areas PA and the transmission areas TA may be alternately arranged in the ±x directions and the ±y directions. The arrangement of the pixels P (or the arrangement of the pixel areas PA) and the arrangement of the transmission areas TA may intersect each other. For example, the arrangement of the pixels P (or the arrangement of the pixel areas PA) extending in the first direction DR1 and the arrangement of the transmission areas TA extending in the first direction DR1 may be alternate in the second direction DR2. By way of example, the arrangement of the pixels P (or the arrangement of the pixel areas PA) extending in the second direction DR2 and the arrangement of the transmission areas TA extending in the second direction DR2 may be alternate in the first direction DR1.

When viewed based on one pixel area PA, the transmission areas TA may be arranged on the top, bottom, left, and right (or the ±x and ±y directions) of the pixel area PA. Another pixel area PA may be arranged in the diagonal direction (or in the first and second directions DR1 and DR2) of the pixel area PA.

When viewed based on one transmission area TA, the pixel areas PA may be arranged above and below the transmission area TA and on the left and right (or the ±x and ±y directions) of the transmission area TA. Another transmission area TA may be arranged in the diagonal direction (or in the first and second directions DR1 and DR2) of the transmission area TA.

In an embodiment, the pixels P may be spaced apart from each other in the diagonal directions of the ±x and ±y directions, for example, in the first direction DR1 and the second direction DR2. By way of example, it may be understood that the pixel areas PA are spaced apart from each other in the first direction DR1 and the second direction DR2. Similarly, the transmission areas TA may be spaced apart from each other in the diagonal directions of the ±x and ±y directions, for example, in the first direction DR1 and the second direction DR2.

Referring to FIG. 2D, the auxiliary electrode AE may extend in the ±x directions.

The auxiliary electrode AE may extend in the ±x directions and may divide the display area DA into pixel areas PA and transmission areas TA. By way of example, auxiliary electrodes AE extending in the ±x directions may be provided. It may be understood that the auxiliary electrodes AE are arranged in the ±y directions and divide the display area DA into pixel areas PA and transmission areas TA.

The pixel areas PA and the transmission areas TA may each have a shape extending in the ±x directions and may be alternately arranged in the ±y directions. An auxiliary electrode may be between one pixel area PA and one transmission area TA, which are adjacent to each other, among the pixel areas PA and the transmission areas TA, which are alternately arranged. In other words, one pixel area PA or one transmission area TA may be between two adjacent auxiliary electrodes AE arranged in the ±y directions.

It may be understood that the auxiliary electrode AE is obtained by removing a portion extending in the ±y directions from the auxiliary electrode AE according to the embodiment illustrated in FIG. 2A.

In an embodiment, pixels P may be arranged in one pixel area PA. For example, the pixel area PA may have a shape extending in the ±x directions, and the pixels P may be arranged in the pixel area PA in the ±x directions.

FIG. 2D illustrates that the pixel area PA and the transmission area TA each have a shape extending in the ±x directions and are alternately arranged in the ±y directions, but the disclosure is not limited thereto. In an embodiment, the pixel area PA and the transmission area TA each have a shape extending in the ±y directions and may be alternately arranged in the ±x directions. The auxiliary electrode AE may have a shape extending in the ±y directions and may be between the pixel area PA and the transmission area TA adjacent to each other.

Referring to FIG. 2E, the auxiliary electrode AE may extend in the ±y directions.

The arrangement of the pixels P (or the pixel areas PA) and the transmission areas TA may be the same as described with reference to FIG. 2A.

The auxiliary electrode AE may extend in the ±y directions and may be between two adjacent pixel areas PA and between two adjacent transmission areas TA.

It may be understood that the auxiliary electrode AE is obtained by removing a portion extending in the ±x directions from the auxiliary electrode AE according to the embodiment illustrated in FIG. 2A.

FIGS. 2A to 2E illustrate that the pixel area PA, the transmission area TA, and the first to third sub-pixels SP1, SP2, and SP3 each have a substantially rectangular shape with angled corners, but the disclosure is not limited thereto. In an embodiment, the pixel area PA, the transmission area TA, and the first to third sub-pixels SP1, SP2, and SP3 may each have an N-gonal shape (where N is a natural number greater than or equal to 3), an elliptical shape, a diamond shape, etc. and may each have various shapes with round corners.

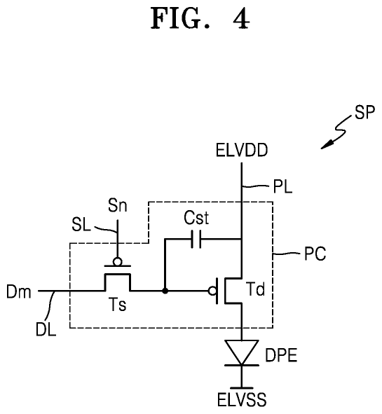

The auxiliary electrode AE illustrated in FIGS. 2A to 2E may include a conductor. The auxiliary electrode AE may extend to the non-display area (see NDA of FIG. 1) and may receive an electrical signal in the non-display area (see NDA of FIG. 1). Accordingly, a selectable voltage (for example, a second power supply voltage (see ELVSS of FIG. 4)) may be applied to the entire auxiliary electrode AE.

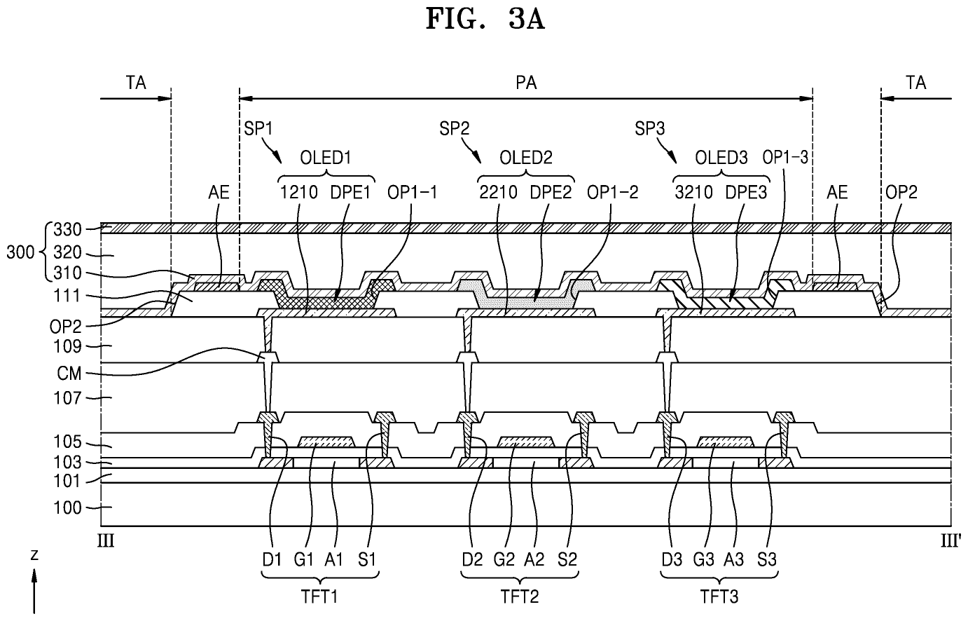

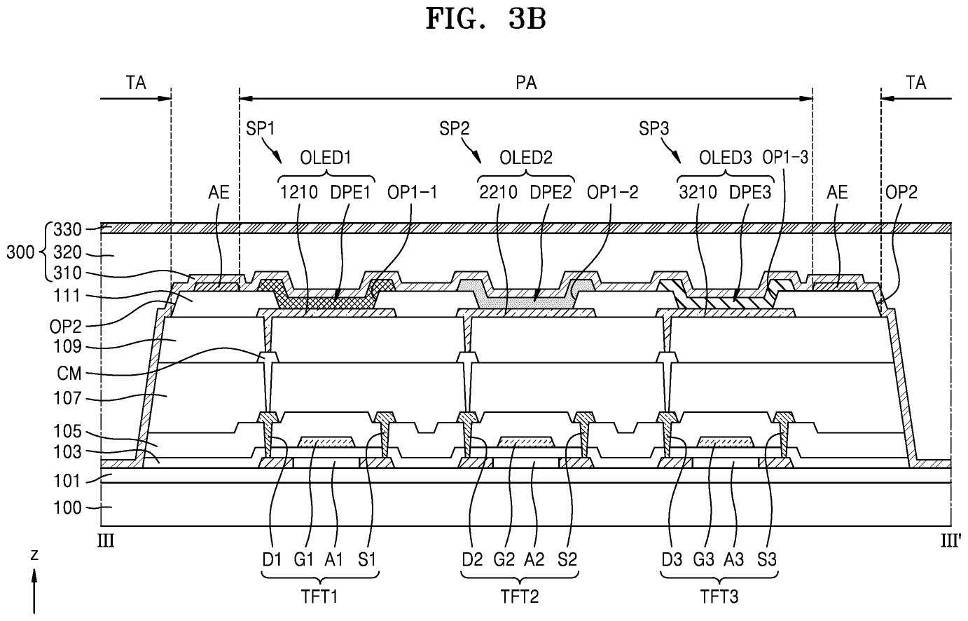

FIGS. 3A and 3B are schematic cross-sectional views schematically illustrating a portion of a display apparatus according to various embodiments.

FIG. 3A may be a schematic cross-sectional view of one of several examples of the embodiment of FIG. 2A taken along line III-III′.

Referring to FIG. 3A, sub-pixels may be disposed on a substrate 100 in a pixel area PA. For example, first to third sub-pixels SP1, SP2, and SP3 may be disposed on the substrate 100. The first to third sub-pixels SP1, SP2, and SP3 may respectively include first to third light-emitting diodes OLED1, OLED2, and OLED3 to emit pieces of light of selectable colors.

The first to third light-emitting diodes OLED1, OLED2, and OLED3 may respectively include first to third sub-pixel electrodes 1210, 2210, and 3210 and first to third display elements DPE1, DPE2, and DPE3.

The substrate 100 may include a glass material or plastic polymer resin. The substrate 100 may include a structure in which a base layer including polymer resin and an inorganic barrier layer including an inorganic insulating material may be stacked each other. The polymer resin may be polyethersulfone (PES), polyether imide (PEI), polyethylene naphthalate (PEN), polyethylene terephthalate (PET), polyphenylene sulfide (PPS), polyarylate (PAR), polyimide (PI), or polycarbonate (PC). In an embodiment, in case that the substrate 100 may include a plastic material or a metal material, flexibility may be improved, compared to in case that the substrate 100 may include a glass material.

The first to third display elements DPE1, DPE2, and DPE3 corresponding to the first to third sub-pixels SP1, SP2, and SP3 may be electrically connected to first to third thin-film transistors TFT1, TFT2, and TFT3 on the substrate 100, respectively.

For example, the first display element DPE1 corresponding to the first sub-pixel SP1 may be electrically connected to the first thin-film transistor TFT1 through the first sub-pixel electrode 1210. The first thin-film transistor TFT1 may include a first active layer A1, a first gate electrode G1 overlapping a portion of the first active layer A1, and a first source electrode S1 and a first drain electrode D1 each in direct contact with a portion of the first active layer A1.

The second display element DPE2 corresponding to the second sub-pixel SP2 may be electrically connected to the second thin-film transistor TFT2 through the second sub-pixel electrode 2210. The second thin-film transistor TFT2 may include a second active layer A2, a second gate electrode G2 overlapping a portion of the second active layer A2, and a second source electrode S2 and a second drain electrode D2 each in direct contact with a portion of the second active layer A2.

The third display element DPE3 corresponding to the third sub-pixel SP3 may be electrically connected to the third thin-film transistor TFT3 through the third sub-pixel electrode 3210. The third thin-film transistor TFT3 may include a third active layer A3, a third gate electrode G3 overlapping a portion of the third active layer A3, and a third source electrode S3 and a third drain electrode D3 each in direct contact with a portion of the third active layer A3.

The first to third gate electrodes G1, G2, and G3 may each include at least one material selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu), and may have a single-layer or multilayer structure including the material described above.

A buffer layer 101 may be between the first to third active layers A1, A2, and A3 and the substrate 100 so as to prevent infiltration of impurities. A gate insulating layer 103 may be between the first to third active layers A1, A2, and A3 and the first to third gate electrodes G1, G2, and G3. An interlayer insulating layer 105 may be disposed on the first to third gate electrodes G1, G2, and G3. The buffer layer 101, the gate insulating layer 103, and the interlayer insulating layer 105 may each include an inorganic insulating material, such as silicon oxide (SiOₓ), silicon nitride (SiNₓ), silicon oxynitride (SiON), aluminum oxide (AlOₓ), aluminum nitride (AlNₓ), titanium oxide (TiOₓ), or titanium nitride (TiNₓ).

The first to third source electrodes S1, S2, and S3 may be disposed on the interlayer insulating layer 105 and may be respectively connected to the first to third active layers A1, A2, and A3 through contact holes formed in the interlayer insulating layer 105 and the gate insulating layer 103. The first to third source electrodes S1, S2, and S3 may each include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), or copper (Cu), and may include a single layer or layers including the material described above.

The first to third drain electrodes D1, D2, and D3 may be disposed on the interlayer insulating layer 105 and may be respectively connected to the first to third active layers A1, A2, and A3 through contact holes formed in the interlayer insulating layer 105 and the gate insulating layer 103. The first to third drain electrodes D1, D2, and D3 may each include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), or copper (Cu), and may include a single layer or layers including the material described above. In an embodiment, the first to third source electrodes S1, S2, and S3 and the first to third drain electrodes D1, D2, and D3 may include the same material or a similar material.

A first organic insulating layer 107 may be disposed on the first to third thin-film transistors TFT1, TFT2, and TFT3. For example, the first organic insulating layer 107 may be disposed to cover the first to third source electrodes S1, S2, and S3 and the first to third drain electrodes D1, D2, and D3. The first organic insulating layer 107 may include an organic insulating material, such as acryl, benzocyclobutene (BCB), PI, or hexamethyldisiloxane (HMDSO). The first organic insulating layer 107 may include contact holes. For example, the first organic insulating layer 107 may include contact holes respectively overlapping the first to third drain electrodes D1, D2, and D3.

A connection metal CM may be disposed on the first organic insulating layer 107. The connection metal CM may include aluminum (Al), copper (Cu), and/or titanium (Ti), and may include a single layer or layers including the material described above. Connection metals CM may be provided. The connection metals CM may be disposed to overlap the first to third drain electrodes D1, D2, and D3, respectively. A portion of each of the connection metals CM may be arranged in a contact hole formed in the first organic insulating layer 107. For example, the connection metals CM may be respectively in direct contact with the first to third drain electrodes D1, D2, and D3 through contact holes formed in the first organic insulating layer 107.

A second organic insulating layer 109 may be between the first organic insulating layer 107 and the first to third sub-pixel electrodes 1210, 2210, and 3210. The second organic insulating layer 109 may include an organic insulating material, such as acryl, BCB, PI, or HMDSO. The second organic insulating layer 109 may include contact holes respectively overlapping the connection metals CM.

The first to third sub-pixel electrodes 1210, 2210, and 3210 may be disposed on the second organic insulating layer 109. The first to third sub-pixel electrodes 1210, 2210, and 3210 may be formed as (semi)transparent electrodes or may be formed as reflective electrodes. In case that the first to third sub-pixel electrodes 1210, 2210, and 3210 are formed as (semi)transparent electrodes, the first to third sub-pixel electrodes 1210, 2210, and 3210 may each include indium tin oxide (ITO), indium zinc oxide (IZO), zinc oxide (ZO), indium oxide (IO), indium gallium oxide (IGO), or aluminum zinc oxide (AZO). In case that the first to third sub-pixel electrodes 1210, 2210, and 3210 are formed as reflective electrodes, a reflective layer may be formed of silver (Ag), magnesium (Mg), aluminum (Al), platinum (Pt), palladium (Pd), gold (Au), nickel (Ni), neodymium (Nd), iridium (Ir), chromium (Cr), or any compound thereof and a layer may be formed of ITO, IZO, ZnO, or In₂O₃ on the reflective layer. In an embodiment, the first to third sub-pixel electrodes 1210, 2210, and 3210 may have a structure in which an ITO layer, an Ag layer, and an ITO layer may be sequentially stacked each other in this stated order. The disclosure is not limited thereto. The first to third sub-pixel electrodes 1210, 2210, and 3210 may be formed of various materials, and the structures of the first to third sub-pixel electrodes 1210, 2210, and 3210 may also be variously modified. For example, the first to third sub-pixel electrodes 1210, 2210, and 3210 may be formed as a single layer or layers.

The first to third sub-pixel electrodes 1210, 2210, and 3210 may be electrically connected to the overlapping connection metals CM through contact holes formed in the second organic insulating layer 109.

According to the embodiment described with reference to FIG. 3A, it is illustrated that the first to third thin-film transistors TFT1, TFT2, and TFT3 and the first to third sub-pixel electrodes 1210, 2210, and 3210 are respectively electrically connected to each other through the connection metals CM, but the disclosure is not limited thereto. In an embodiment, the connection metals CM may be omitted, and one organic insulating layer may be between the first to third thin-film transistors TFT1, TFT2, and TFT3 and the first to third sub-pixel electrodes 1210, 2210, and 3210. By way of example, three or more organic insulating layers may be between the first to third thin-film transistors TFT1, TFT2, and TFT3 and the first to third sub-pixel electrodes 1210, 2210, and 3210, and the first to third thin-film transistors TFT1, TFT2, and TFT3 may be respectively electrically connected to the first to third sub-pixel electrodes 1210, 2210, and 3210 through connection metals.

A bank layer 111 may cover the edge areas (or edges) of the first to third sub-pixel electrodes 1210, 2210, and 3210. In other words, the bank layer 111 may include openings respectively exposing central portions of the first to third sub-pixel electrodes 1210, 2210, and 3210. For example, the bank layer 111 may include a 1^{st}-1 opening OP1-1 overlapping the first sub-pixel electrode 1210. The bank layer 111 may include a 1^{st}-2 opening OP1-2 overlapping the second sub-pixel electrode 2210. The bank layer 111 may include 1^{st}-3 opening OP1-3 overlapping the third sub-pixel electrode 3210.

The openings of the bank layer 111 may respectively define emission areas of the first to third sub-pixels SP1, SP2, and SP3. For example, a 3^{rd}-1 opening OP1-1 may define the emission area of the first sub-pixel SP1. A 3^{rd}-2 opening OP1-2 may define the emission area of the second sub-pixel SP2. A 3^{rd}-3 opening OP1-3 may define the emission area of the third sub-pixel SP3.

No bank layer may be arranged in the transmission area TA. In other words, the bank layer 111 may include a second opening OP2 overlapping the transmission area TA.

The first to third display elements DPE1, DPE2, and DPE3 may be respectively disposed on the first to third sub-pixel electrodes 1210, 2210, and 3210. For example, the first display element DPE1 may be disposed on the first sub-pixel electrode 1210. The second display element DPE2 may be disposed on the second sub-pixel electrode 2210. The third display element DPE3 may be disposed on the third sub-pixel electrode 3210.

A portion of each of the first to third display elements DPE1, DPE2, and DPE3 may be disposed on the bank layer 111. For example, the edge area (or edge) of the first display element DPE1 may be disposed on a portion of the bank layer 111 overlapping the edge area (or edge) of the first sub-pixel electrode 1210. The edge area (or edge) of the second display element DPE2 may be disposed on a portion of the bank layer 111 overlapping the edge area (or edge) of the second sub-pixel electrode 2210. The edge area (or edge) of the third display element DPE3 may be disposed on a portion of the bank layer 111 overlapping the edge area (or edge) of the third sub-pixel electrode 3210. Therefore, a portion of the bank layer 111 may be between the edge area (or edge) of each of the first to third display elements DPE1, DPE2, and DPE3 and the edge area (or edge) of each of the first to third sub-pixel electrodes 1210, 2210, and 3210.

The first to third display elements DPE1, DPE2, and DPE3 may include layers each including an emission layer and an opposite electrode corresponding thereto.

The auxiliary electrode AE may be disposed on the bank layer 111. For example, the auxiliary electrode AE may be disposed on the bank layer 111 and may be between the first sub-pixel SP1 and the transmission area TA adjacent to the first sub-pixel SP1. The auxiliary electrode AE may be disposed on the bank layer 111 and may be between the third sub-pixel SP3 and the transmission area TA adjacent to the third sub-pixel SP3.

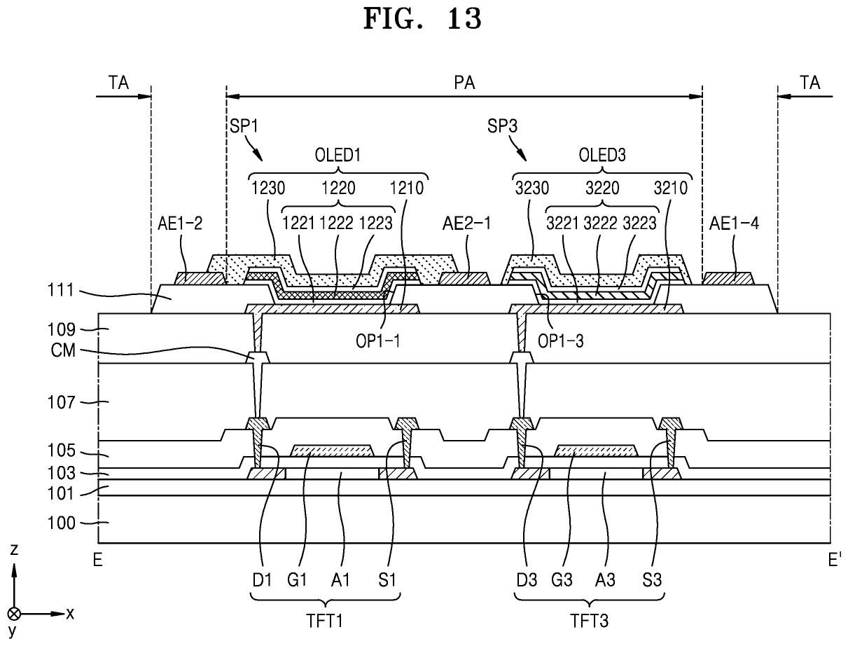

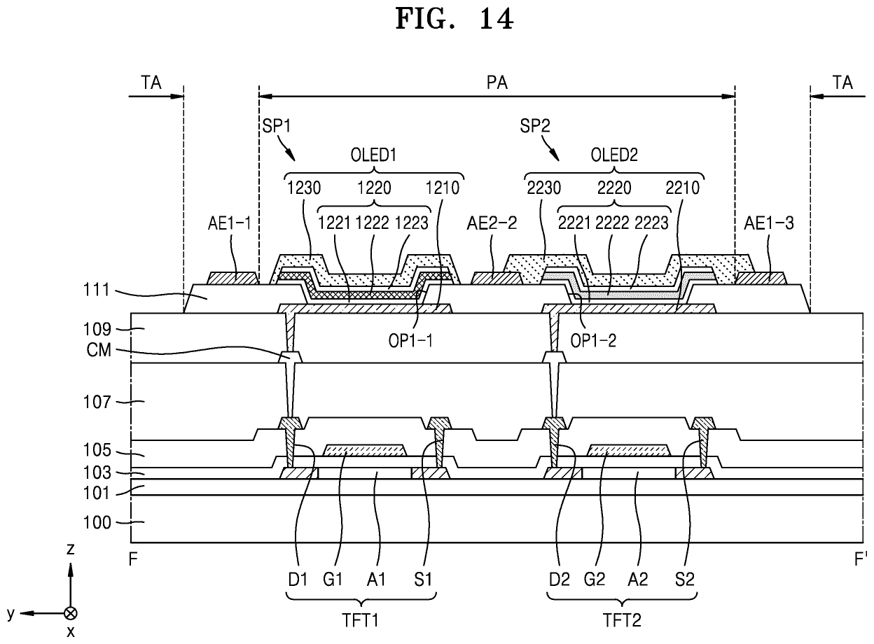

FIG. 3A illustrates that the auxiliary electrodes AE are not between the first sub-pixel SP1 and the second sub-pixel SP2 and between the second sub-pixel SP2 and the third sub-pixel SP3, but the disclosure is not limited thereto. In an embodiment, the auxiliary electrodes AE may be between the first sub-pixel SP1 and the second sub-pixel SP2 and/or between the second sub-pixel SP2 and the third sub-pixel SP3 (see FIGS. 13 and 14).

FIG. 3A illustrates that the first and third display elements DPE1 and DPE3 and the auxiliary electrodes AE are spaced apart from each other, but the disclosure is not limited thereto. In an embodiment, the first and third display elements DPE1 and DPE3 may be respectively in contact with the auxiliary electrodes AE adjacent thereto.

An encapsulation layer 300 may be disposed to cover the first to third light-emitting diodes OLED1, OLED2, and OLED3, the bank layer 111, and the auxiliary electrodes AE. The encapsulation layer 300 may include at least one inorganic encapsulation layer and at least one organic encapsulation layer. For example, the encapsulation layer 300 may include a first inorganic encapsulation layer 310 disposed on the first to third light-emitting diodes OLED1, OLED2, and OLED3, a second inorganic encapsulation layer 330, and an organic encapsulation layer 320 between the first and second inorganic encapsulation layers 310 and 330.

The first inorganic encapsulation layer 310 may overlap the first to third light-emitting diodes OLED1, OLED2, and OLED3 and the auxiliary electrodes AE and cover the first to third light-emitting diodes OLED1, OLED2, and OLED3 and the auxiliary electrodes AE.

The first and second inorganic encapsulation layers 310 and 330 may include at least one inorganic insulating material selected from aluminum oxide (AlOₓ), titanium oxide (TiOₓ), tantalum oxide (TaOₓ), hafnium oxide (HfOₓ), zinc oxide (ZnOₓ), silicon oxide (SiOₓ), silicon nitride (SiNₓ), and silicon oxynitride (SiON).

The organic encapsulation layer 320 may be between the first and second inorganic encapsulation layers 310 and 330 and may act as a planarization layer.

The organic encapsulation layer 320 may include at least one organic insulating material selected from PET, PEN, PC, PI, PES, polyoxymethylene (POM), PAR, and HMDSO.

The encapsulation layer 300 may be disposed to cover all of the transmission area TA, the pixel area PA, and the auxiliary electrode AE. A portion of each of the first inorganic encapsulation layer 310 and the organic encapsulation layer 320 may be arranged in the second opening OP2 of the bank layer 111. The first inorganic encapsulation layer 310 and the organic encapsulation layer 320 may at least partially (for example, completely) fill the second opening OP2. Because the bank layer 111 is not arranged in the transmission area TA, the first inorganic encapsulation layer 310 may be in direct contact with the second organic insulating layer 109 in the transmission area TA.

FIG. 3B may be a schematic cross-sectional view of one of several examples of the embodiment of FIG. 2A taken along line III-III′.

Referring to FIG. 3B, there is a difference in characteristics in the transmission area TA from the embodiment illustrated in FIG. 3A, which will be described in detail below.

As illustrated in FIG. 3B, at least one insulating layer between the substrate 100 and the first to third sub-pixel electrodes 1210, 2210, and 3210 may include an opening corresponding to the transmission area TA.

For example, the gate insulating layer 103, the interlayer insulating layer 105, the first organic insulating layer 107, and/or the second organic insulating layer 109 may each include an opening overlapping the transmission area TA. The openings of the gate insulating layer 103, the interlayer insulating layer 105, the first organic insulating layer 107, and/or the second organic insulating layer 109 may overlap the second opening OP2 of the bank layer 111. In other words, the gate insulating layer 103, the interlayer insulating layer 105, the first organic insulating layer 107, the second organic insulating layer 109, and the bank layer 111 may not be arranged in the transmission area TA.

It may be understood that the embodiment illustrated in FIG. 3B is obtained by removing, from the embodiment illustrated in FIG. 3A, the gate insulating layer 103, the interlayer insulating layer 105, the first organic insulating layer 107, and the second organic insulating layer 109 in the range overlapping the transmission area TA.

Portions of the first inorganic encapsulation layer 310 and the organic encapsulation layer 320 may be arranged in the openings formed through the gate insulating layer 103, the interlayer insulating layer 105, the first organic insulating layer 107, and the second organic insulating layer 109 in the transmission area TA. For example, the first inorganic encapsulation layer 310 and the organic encapsulation layer 320 may at least partially (for example, completely) fill the openings formed through the gate insulating layer 103, the interlayer insulating layer 105, the first organic insulating layer 107, and the second organic insulating layer 109 in the transmission area TA.

The first inorganic encapsulation layer 310 may cover the side surfaces of the gate insulating layer 103, the interlayer insulating layer 105, the first organic insulating layer 107, the second organic insulating layer 109, and the bank layer 111. The first inorganic encapsulation layer 310 may be in direct contact with the upper surface of the buffer layer 101 in the transmission area TA.

FIG. 3B illustrates that the insulating layers between the substrate 100 and the first to third sub-pixel electrodes 1210, 2210, and 3210 include openings corresponding to the transmission area TA, but the disclosure is not limited thereto. Therefore, one or more insulating layers selected from the bank layer 111, the second organic insulating layer 109, the first organic insulating layer 107, the interlayer insulating layer 105, and the gate insulating layer 103 may include openings corresponding to the transmission area TA.

An embodiment in which the bank layer 111 and the second organic insulating layer 109 are removed from the transmission area TA, for example, an embodiment in which the bank layer 111 and the second organic insulating layer 109 include openings overlapping the transmission area TA and the first inorganic encapsulation layer 310 is in direct contact with the first organic insulating layer 107 in the transmission area TA, may also be included in one of various embodiments.

An embodiment in which the bank layer 111, the second organic insulating layer 109, and the first organic insulating layer 107 are removed from the transmission area TA, for example, an embodiment in which the bank layer 111, the second organic insulating layer 109, and the first organic insulating layer 107 include openings overlapping the transmission area TA and the first inorganic encapsulation layer 310 is in direct contact with the interlayer insulating layer 105 in the transmission area TA, may also be included in one of various embodiments.

FIG. 4 is a schematic diagram of an equivalent circuit schematically illustrating a sub-pixel SP of a display apparatus, according to an embodiment.

The sub-pixel SP may be the first to third sub-pixels SP1, SP2, and SP3 of FIG. 2A. A display element DPE may be the first to third display elements DPE1, DPE2, and DPE3 of FIG. 3A.

The sub-pixel SP may include a sub-pixel circuit PC and the display element DPE connected to the sub-pixel circuit PC. The sub-pixel circuit PC may include a driving thin-film transistor Td, a switching thin-film transistor Ts, and a storage capacitor Cst. The sub-pixel SP may emit light of a selectable color through the display element DPE. For example, the sub-pixel SP may emit red light, green light, or blue light through the display element DPE, or may emit red light, green light, blue light, or white light through the display element DPE.

The switching thin-film transistor Ts may be connected to a scan line SL and a data line DL and may transmit, to the driving thin-film transistor Td, a data voltage or a data signal Dm input from the data line DL in response to a scan voltage or a scan signal Sn input from the scan line SL.

The storage capacitor Cst may be connected to the switching thin-film transistor Ts and a driving voltage line PL, and may store a voltage corresponding to a difference between a voltage received from the switching thin-film transistor Ts and a first power supply voltage ELVDD supplied to the driving voltage line PL.

The driving thin-film transistor Td may be connected to the driving voltage line PL and the storage capacitor Cst, and may control a driving current flowing from the driving voltage line PL to the display element DPE according to a voltage value stored in the storage capacitor Cst. The display element DPE may emit light having a selectable luminance according to the driving current. An opposite electrode (for example, a cathode) of the display element DPE may receive a second power supply voltage ELVSS. In an embodiment, the opposite electrode of the display element DPE may receive the second power supply voltage ELVSS through an auxiliary electrode.

FIG. 4 illustrates that the sub-pixel circuit PC may include two thin-film transistors and one storage capacitor, but the disclosure is not limited thereto, and the sub-pixel circuit PC may include three or more thin-film transistors.

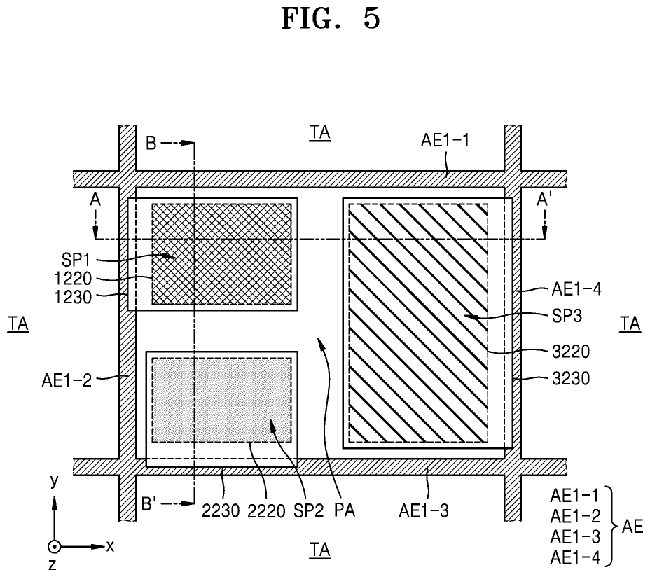

FIG. 5 is an enlarged schematic plan view illustrating a portion of a display apparatus according to an embodiment.

For example, FIG. 5 may be an enlarged view of a portion of the embodiment illustrated in FIG. 2C. Accordingly, the transmission areas TA may be arranged on the top, bottom, left, and right (or the ±x and ±y directions) of the pixel area PA. The following description will focus on a case where the transmission areas TA are arranged on the top, bottom, left, and right (or the ±x and ±y directions) of the pixel area PA. However, the disclosure is not limited thereto, and the following description may be similarly applied to a case where the transmission areas TA are arranged on the top and bottom (or the ±y directions) of the pixel area (see FIGS. 2A, 2B, and 2D) or a case where the transmission areas TA are arranged on the left and right (or the ±x directions) of the pixel area DPA (see FIG. 2E).

Referring to FIG. 5, the auxiliary electrode AE may be disposed to surround the pixel area PA, and the transmission areas TA may be arranged around the pixel area PA. For example, the transmission areas TA may be arranged on the top, bottom, left, and right (or the ±x and ±y directions) of the pixel area PA. The pixel area PA and the transmission area TA may be spaced apart from each other by the auxiliary electrode AE.

The first to third sub-pixels SP1, SP2, and SP3 may be arranged in the pixel area PA. The auxiliary electrode AE may substantially surround the first to third sub-pixels SP1, SP2, and SP3.

The first to third sub-pixels SP1, SP2, and SP3 may respectively include first to third intermediate layers 1220, 2220, and 3220 and first to third opposite electrodes 1230, 2230, and 3230. For example, the first sub-pixel SP1 may include the first intermediate layer 1220 and the first opposite electrode 1230. The second sub-pixel SP2 may include the second intermediate layer 2220 and the second opposite electrode 2230. The third sub-pixel SP3 may include the third intermediate layer 3220 and the third opposite electrode 3230.

The first to third intermediate layers 1220, 2220, and 3220 may include materials that emit pieces of light of different colors in case that a voltage is applied thereto. For example, the first intermediate layer 1220 may include a material that emits red light. The second intermediate layer 2220 may include a material that emits green light. The third intermediate layer 3220 may include a material that emits blue light.

Accordingly, the first to third sub-pixels SP1, SP2, and SP3 may emit pieces of light of different colors. For example, the first sub-pixel SP1 may emit red light. The second sub-pixel SP2 may emit green light. The third sub-pixel SP3 may emit blue light.

The areas of the first to third opposite electrodes 1230, 2230, and 3230 may be respectively greater than the areas of the first to third intermediate layers 1220, 2220, and 3220. For example, the area of the first opposite electrode 1230 may be greater than the area of the first intermediate layer 1220. Accordingly, the first opposite electrode 1230 may completely cover the first intermediate layer 1220 when viewed from the +z direction. The area of the second opposite electrode 2230 may be greater than the area of the second intermediate layer 2220. Accordingly, the second opposite electrode 2230 may completely cover the second intermediate layer 2220 when viewed from the +z direction. The area of the third opposite electrode 3230 may be greater than the area of the third intermediate layer 3220. Accordingly, the third opposite electrode 3230 may completely cover the third intermediate layer 3220 when viewed from the +z direction.

The first to third sub-pixels SP1, SP2, and SP3 may have island shapes spaced apart from each other. For example, the first to third intermediate layers 1220, 2220, and 3220 may be spaced apart from each other. The first to third opposite electrodes 1230, 2230, and 3230 may be spaced apart from each other.

The auxiliary electrode AE may include 1^{st}-1 to 1^{st}-4 portions AE1-1, AE1-2, AE1-3, and AE1-4. The 1^{st}-1 portion AE1-1 may be disposed on the top (or the +y direction) of the pixel area PA and may extend in the ±x directions. The 1^{st}-2 portion AE1-2 may be disposed on the left (or the −x direction) of the pixel area PA and may extend in the ±y directions. The 1^{st}-3 portion AE1-3 may be disposed on the bottom (or the −y direction) of the pixel area PA and may extend in the ±x directions. The 1^{st}-4 portion AE1-4 may be disposed on the right (or the +x direction) of the pixel area PA and may extend in the ±y directions.

The first to third opposite electrodes 1230, 2230, and 3230 may be respectively disposed on the first to third intermediate layers 1220, 2220, and 3220, may extend in one direction, and may be in contact with the auxiliary electrode AE. Portions of the first to third opposite electrodes 1230, 2230, and 3230 that are in contact with the auxiliary electrode AE may be different from each other. For example, the first opposite electrode 1230 may be in contact with the 1^{st}-2 portion AE1-2, the second opposite electrode 2230 may be in contact with the 1^{st}-3 portion AE1-3, and the third opposite electrode 3230 may be in contact with the 1^{st}-4 portion AE1-4.

For example, the first opposite electrode 1230 may be disposed on the first intermediate layer 1220, may extend in the −x direction, and may extend beyond the edge of the first intermediate layer 1220 and overlap the 1^{st}-2 portion AE1-2 of the auxiliary electrode AE. The first opposite electrode 1230 may be in direct contact with the 1^{st}-2 portion AE1-2 of the auxiliary electrode AE.

The second opposite electrode 2230 may be disposed on the second intermediate layer 2220, may extend in the −y, and may extend beyond the edge of the second intermediate layer 2220 and overlap the 1^{st}-3 portion AE1-3 of the auxiliary electrode AE. The second opposite electrode 2230 may be in direct contact with the 1^{st}-3 portion AE1-3 of the auxiliary electrode AE.

The third opposite electrode 3230 may be disposed on the third intermediate layer 3220, may extend in +x direction, and may extend beyond the edge of the third intermediate layer 3220 and overlap the 1^{st}-4 portion AE1-4 of the auxiliary electrode AE. The third opposite electrode 3230 may be in direct contact with the 1^{st}-4 portion AE1-4 of the auxiliary electrode AE.

The disclosure is not limited to the extending directions of the first to third opposite electrodes 1230, 2230, and 3230. In an embodiment, both the first and second opposite electrodes 1230 and 2230 may extend in the −x direction and may be in contact with the same portion (for example, the 1^{st}-2 portion AE1-2) of the auxiliary electrode AE. In an embodiment, both the first and second opposite electrodes 1230 and 3230 may extend in the +y direction and may be in contact with the same portion (for example, the 1^{st}-1 portion AE1-1) of the auxiliary electrode AE.

The auxiliary electrode AE may extend to the non-display area (see NDA of FIG. 1) and may receive a selectable voltage (for example, a second power supply voltage (see ELVSS of FIG. 4)). Because the first to third opposite electrodes 1230, 2230, and 3230 are in contact with the auxiliary electrode AE, the first to third opposite electrodes 1230, 2230, and 3230 may also receive the same voltage (for example, the second power supply voltage (see ELVSS of FIG. 4)) as the voltage applied to the auxiliary electrode AE.

For example, the first opposite electrode 1230 may receive a voltage in contact with the 1^{st}-2 portion AE1-2, the second opposite electrode 2230 may receive a voltage in contact with the 1^{st}-3 portion AE1-3, and the third opposite electrode 3230 may receive a voltage in contact with the 1^{st}-4 portion AE1-4.

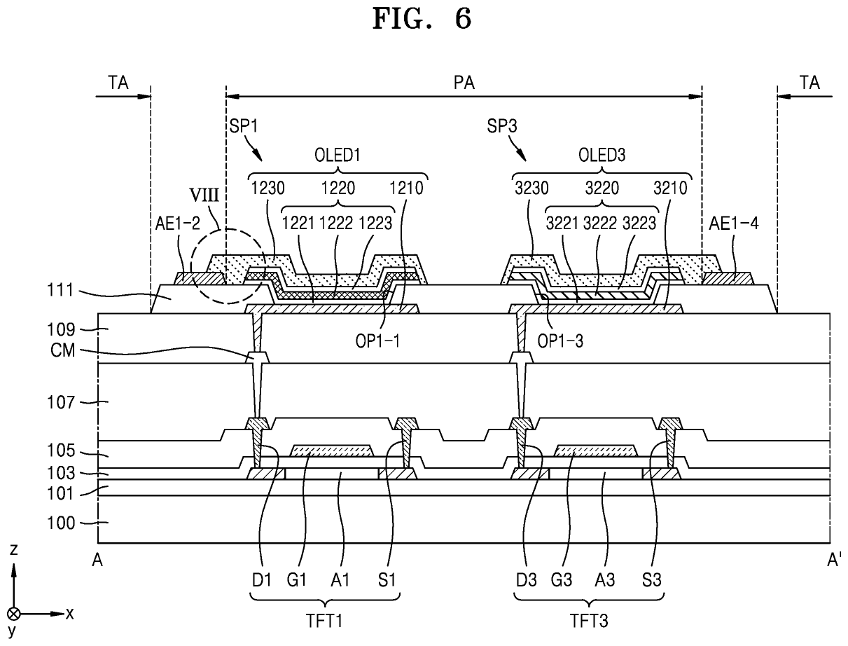

FIG. 6 is an enlarged schematic cross-sectional view illustrating a portion of a display apparatus according to an embodiment.

FIG. 6 is a schematic cross-sectional view of the embodiment of FIG. 5 taken along line A-A′ of FIG. 5.

The first intermediate layer 1220 may be disposed on the first sub-pixel electrode 1210. A portion of the first intermediate layer 1220 may be arranged in the 1^{st}-1 opening OP1-1 of the bank layer 111 and may be in direct contact with the first sub-pixel electrode 1210. A portion of the first intermediate layer 1220 may be disposed on the bank layer 111. Accordingly, a portion of the bank layer 111 may be between the edge area (or edge) of the first intermediate layer 1220 and the edge area (or edge) of the first sub-pixel electrode 1210.

The first intermediate layer 1220 may include 1^{st}-1 and 1^{st}-2 functional layers 1221 and 1223, and a first emission layer 1222 between the 1^{st}-1 and 1^{st}-2 functional layers 1221 and 1223.

The first emission layer 1222 may include an organic material that emits a selectable color. For example, the first emission layer 1222 may include an organic material that emits red light. In an embodiment, the first emission layer 1222 may include an inorganic material.

The 1^{st}-1 functional layer 1221 may be between the first sub-pixel electrode 1210 and the first emission layer 1222. The 1^{st}-1 functional layer 1221 may have a single-layer or multilayer structure including a hole injection layer and/or a hole transport layer.

The 1^{st}-2 functional layer 1223 may be between the first emission layer 1222 and the first opposite electrode 1230. The 1^{st}-2 functional layer 1223 may have a single-layer or multilayer structure including an electron transport layer and/or an electron injection layer.

In an embodiment, the positions of the 1^{st}-1 functional layer 1221 and/or the 1^{st}-2 functional layer 1223 may be changed to each other. 1^{st}-1 functional layers 1221 and/or 1^{st}-2 functional layers 1223 may be provided. By way of example, the 1^{st}-1 functional layer 1221 and/or the 1^{st}-2 functional layer 1223 may be omitted.

The third intermediate layer 3220 may be disposed on a third sub-pixel electrode 3210. A portion of the third intermediate layer 3220 may be arranged in the 1^{st}-3 opening OP1-3 of the bank layer 111 and may be in direct contact with the third sub-pixel electrode 3210. A portion of the third intermediate layer 3220 may be disposed on the bank layer 111. Accordingly, a portion of the bank layer 111 may be between the edge area (or edge) of the third intermediate layer 3220 and the edge area (or edge) of the third sub-pixel electrode 3210.

The third intermediate layer 3220 may include 3^{rd}-1 and 3^{rd}-2 functional layers 3221 and 3223, and a third emission layer 3222 between the 3^{rd}-1 and 3^{rd}-2 functional layers 3221 and 3223.

The third emission layer 3222 may include an organic material that emits a selectable color. For example, the third emission layer 3222 may include an organic material that emits blue light. In an embodiment, the third emission layer 3222 may include an inorganic material.

The 3^{rd}-1 functional layer 3221 may be between the third sub-pixel electrode 3210 and the third emission layer 3222. The 3^{rd}-1 functional layer 3221 may have a single-layer or multilayer structure including a hole injection layer and/or a hole transport layer.

The 3^{rd}-2 functional layer 3223 may be between the third emission layer 3222 and the third opposite electrode 3230. The 3^{rd}-2 functional layer 3223 may have a single-layer or multilayer structure including an electron transport layer and/or an electron injection layer.

In an embodiment, the positions of the 3^{rd}-1 functional layer 3221 and/or the 3^{rd}-2 functional layer 3223 may be changed to each other. 3^{rd}-1 functional layers 3221 and/or 3^{rd}-2 functional layers 3223 may be provided. By way of example, the 3^{rd}-1 functional layer 3221 and/or the 3^{rd}-2 functional layer 3223 may be omitted.

The first opposite electrode 1230 may be disposed on the bank layer 111 and cover the first intermediate layer 1220.

The 1^{st}-2 portion AE1-2 of the auxiliary electrode may be arranged adjacent to the first opposite electrode 1230 and disposed on the bank layer 111. For example, the 1^{st}-2 portion AE1-2 may be disposed on the bank layer 111 in the −x direction of the first opposite electrode 1230. In other words, the 1^{st}-2 portion AE1-2 may be disposed on the bank layer 111 between the first opposite electrode 1230 and the transmission area TA adjacent to the first opposite electrode 1230. By way of example, the 1^{st}-2 portion AE1-2 may be disposed on the bank layer 111 between the pixel area PA and the transmission area TA arranged in the −x direction of the pixel area PA.

A portion of the first opposite electrode 1230 may extend beyond the edge of the first intermediate layer 1220 and overlap the 1^{st}-2 portion AE1-2. In an embodiment, a portion of the first opposite electrode 1230 may cover the +x side edge and the side surface of the first intermediate layer 1220. On the other hand, a portion of the opposite side of the first opposite electrode 1230 may extend in the −x direction beyond the −x side edge of the first intermediate layer 1220 and overlap the 1^{st}-2 portion AE1-2. The first opposite electrode 1230 may be in direct contact with the 1^{st}-2 portion AE1-2. Accordingly, the first opposite electrode 1230 may receive a voltage through the 1^{st}-2 portion AE1-2.

The third opposite electrode 3230 may be disposed on the bank layer 111 and cover the third intermediate layer 3220.

The 1^{st}-4 portion AE1-4 of the auxiliary electrode may be arranged adjacent to the third opposite electrode 3230 and disposed on the bank layer 111. For example, the 1^{st}-4 portion AE1-4 may be disposed on the bank layer 111 in the +x direction of the third opposite electrode 3230. In other words, the 1^{st}-4 portion AE1-4 may be disposed on the bank layer 111 between the third opposite electrode 3230 and the transmission area TA adjacent to the third opposite electrode 3230. By way of example, the 1^{st}-4 portion AE1-4 may be disposed on the bank layer 111 between the pixel area PA and the transmission area TA arranged in the +x direction of the pixel area PA.

A portion of the third opposite electrode 3230 may extend beyond the edge of the third intermediate layer 3220 and overlap the 1^{st}-4 portion AE1-4. In an embodiment, a portion of the third opposite electrode 3230 may cover the −x side edge and the side surface of the third intermediate layer 3220. On the other hand, a portion of the opposite side of the third opposite electrode 3230 may extend in the +x direction beyond the +x side edge of the third intermediate layer 3220 and overlap the 1^{st}-4 portion AE1-4. The third opposite electrode 3230 may be in direct contact with the 1^{st}-4 portion AE1-4. Accordingly, the third opposite electrode 3230 may receive a voltage through the 1^{st}-4 portion AE1-4.

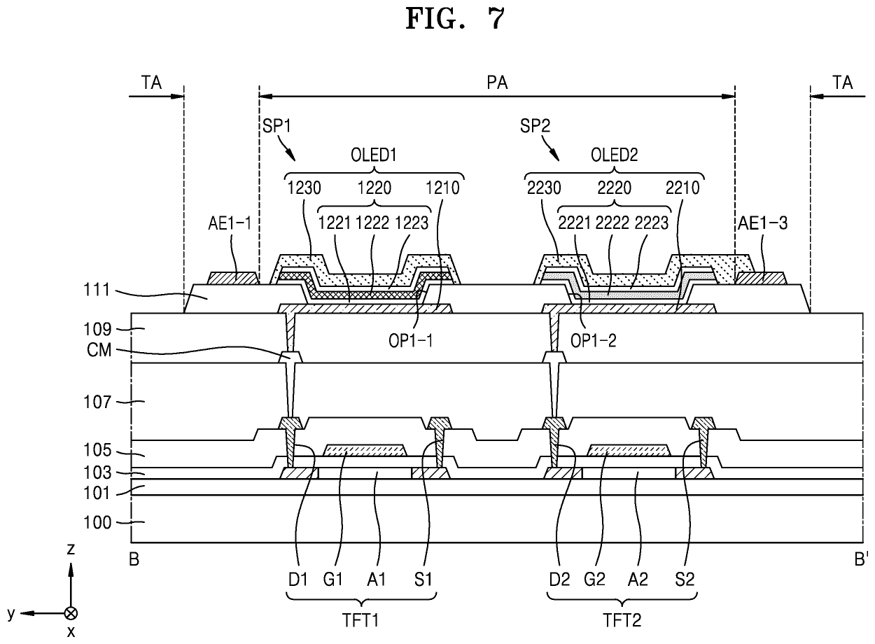

FIG. 7 is an enlarged schematic cross-sectional view illustrating a portion of a display apparatus according to an embodiment.

FIG. 7 is a schematic cross-sectional view of the embodiment of FIG. 5 taken along line B-B′ of FIG. 5.

The second intermediate layer 2220 may be disposed on the second sub-pixel electrode 2210. A portion of the second intermediate layer 2220 may be arranged in the 1^{st}-2 opening OP1-2 of the bank layer 111 and may be in direct contact with the second sub-pixel electrode 2210. A portion of the second intermediate layer 2220 may be disposed on the bank layer 111. Accordingly, a portion of the bank layer 111 may be between the edge area (or edge) of the second intermediate layer 2220 and the edge area (or edge) of the second sub-pixel electrode 2210.

The second intermediate layer 2220 may include 2^{nd}-1 and 2^{nd}-2 functional layers 2221 and 2223, and a second emission layer 2222 between the 2^{nd}-1 and 2^{nd}-2 functional layers 2221 and 2223.

The second emission layer 2222 may include an organic material that emits a selectable color. For example, the second emission layer 2222 may include an organic material that emits green light. In an embodiment, the second emission layer 2222 may include an inorganic material.

The 2^{nd}-1 functional layer 2221 may be between the second sub-pixel electrode 2210 and the second emission layer 2222. The 2^{nd}-1 functional layer 2221 may have a single-layer or multilayer structure including a hole injection layer and/or a hole transport layer.

The 2^{nd}-2 functional layer 2223 may be between the second emission layer 2222 and a second opposite electrode 2230. The 2^{nd}-2 functional layer 2223 may have a single-layer or multilayer structure including an electron transport layer and/or an electron injection layer.

In an embodiment, the positions of the 2^{nd}-1 functional layer 2221 and/or the 2^{nd}-2 functional layer 2223 may be changed to each other. 2^{nd}-1 functional layers 2221 and/or 2^{nd}-2 functional layers 2223 may be provided. By way of example, the 2^{nd}-1 functional layer 2221 and/or the 2^{nd}-2 functional layer 2223 may be omitted.

The first opposite electrode 1230 may be disposed on the bank layer 111 and cover the first intermediate layer 1220.

The 1^{st}-1 portion AE1-1 of the auxiliary electrode may be arranged adjacent to the first opposite electrode 1230 and disposed on the bank layer 111. For example, the 1^{st}-1 portion AE1-1 may be disposed on the bank layer 111 in the +y direction of the first opposite electrode 1230. In other words, the 1^{st}-1 portion AE1-1 may be disposed on the bank layer 111 between the first opposite electrode 1230 and the transmission area TA adjacent to the first opposite electrode 1230. By way of example, the 1^{st}-1 portion AE1-1 may be disposed on the bank layer 111 between the pixel area PA and the transmission area TA arranged in the +y direction of the pixel area PA.

The first opposite electrode 1230 may cover the ±y side edge and the side surface of the first intermediate layer 1220. The first opposite electrode 1230 may extend beyond the +y edge of the first intermediate layer 1220 and overlap the 1^{st}-1 portion AE1-1.

The second opposite electrode 2230 may be disposed on the bank layer 111 and cover the second intermediate layer 2220.

The 1^{st}-3 portion AE1-3 of the auxiliary electrode may be arranged adjacent to the second opposite electrode 2230 and disposed on the bank layer 111. For example, the 1^{st}-3 portion AE1-3 may be disposed on the bank layer 111 in the −y direction of the second opposite electrode 2230. In other words, the 1^{st}-3 portion AE1-3 may be disposed on the bank layer 111 between the second opposite electrode 2230 and the transmission area TA adjacent to the second opposite electrode 2230. By way of example, the 1^{st}-3 portion AE1-3 may be disposed on the bank layer 111 between the pixel area PA and the transmission area TA arranged in the −y direction of the pixel area PA.

A portion of the second opposite electrode 2230 may extend beyond the edge of the second intermediate layer 2220 and overlap the 1^{st}-3 portion AE1-3. In an embodiment, a portion of the second opposite electrode 2230 may cover the +y side edge and the side surface of the second intermediate layer 2220. On the other hand, a portion of the opposite side of the second opposite electrode 2230 may extend in the −y direction beyond the −y side edge of the second intermediate layer 2220 and overlap the 1^{st}-3 portion AE1-3. The second opposite electrode 2230 may be in direct contact with the 1^{st}-3 portion AE1-3. Accordingly, the second opposite electrode 2230 may receive a voltage through the 1^{st}-3 portion AE1-3.

FIGS. 6 and 7 illustrate that the bank layer 111 is not present in the transmission area TA. However, as described with reference to FIGS. 3A and 3B, an embodiment in which any layer from the bank layer 111 to a layer selected from the second organic insulating layer 109, the first organic insulating layer 107, the interlayer insulating layer 105, and the gate insulating layer 103 is not present in the transmission area TA may be included in the embodiments.

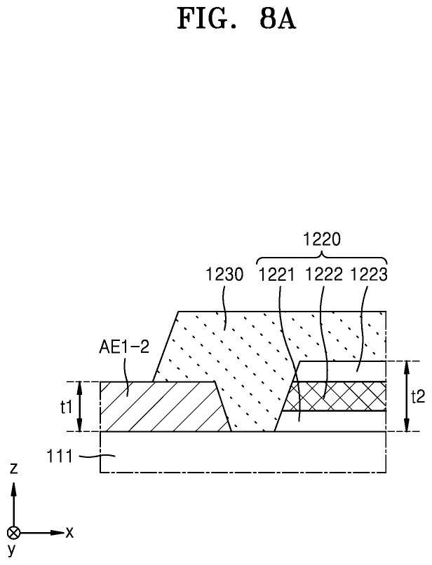

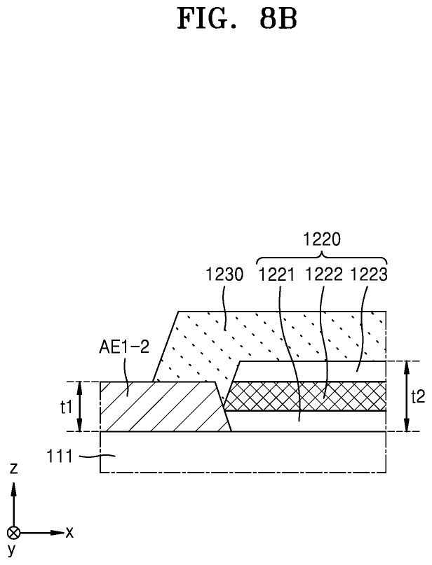

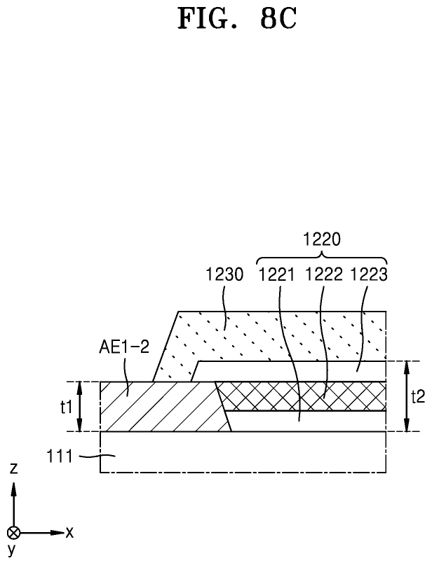

FIGS. 8A to 8C are enlarged schematic cross-sectional views illustrating a portion of a display apparatus according to various embodiments.

The embodiment illustrated in FIG. 8A may be one of several examples illustrating an enlarged area VIII in the embodiment illustrated in FIG. 6.

Referring to FIG. 8A, the 1^{st}-2 portion AE1-2 of the auxiliary electrode and the first intermediate layer 1220 may be disposed on the bank layer 111. The first opposite electrode 1230 may be disposed to cover a portion of the upper surface of the 1^{st}-2 portion AE1-2 and the first intermediate layer 1220.

The 1^{st}-2 portion AE1-2 and the first intermediate layer 1220 may be spaced apart from each other. In an embodiment, the 1^{st}-2 portion AE1-2 and the first intermediate layer 1220 may be spaced apart from each other, and a portion of the first opposite electrode 1230 may be in direct contact with the bank layer 111 between the 1^{st}-2 portion AE1-2 and the first intermediate layer 1220.

A thickness t2 of the first intermediate layer 1220 may be greater than a thickness t1 of the 1^{st}-2 portion AE1-2. However, the disclosure is not necessarily limited thereto, and in an embodiment, the thickness t2 of the first intermediate layer 1220 may be substantially equal to the thickness t1 of the 1^{st}-2 portion AE1-2.

The embodiment illustrated in FIG. 8B may be another one of several examples illustrating an enlarged area VIII in the embodiment illustrated in FIG. 6.

Referring to FIG. 8B, the 1^{st}-2 portion AE1-2 and the first intermediate layer 1220 may be in direct contact with each other. For example, one surface of the 1^{st}-2 portion AE1-2 may be in contact with one surface of the first intermediate layer 1220. A portion of the first intermediate layer 1220 (for example, a portion of a 1^{st}-1 functional layer 1221) may be disposed on the side surface of the 1^{st}-2 portion AE1-2 facing the first intermediate layer 1220. Accordingly, the 1^{st}-2 portion AE1-2 may have a shape that appears to dig into a portion of the side surface of the first intermediate layer 1220. In other words, the first intermediate layer 1220 may cover a portion of the side surface of the 1^{st}-2 portion AE1-2.

The embodiment illustrated in FIG. 8C may be another one of several examples illustrating an enlarged area VIII in the embodiment illustrated in FIG. 6.

Referring to FIG. 8C, the first intermediate layer 1220 may cover a portion of the side surface and the upper surface of the 1^{st}-2 portion AE1-2. Therefore, a portion of the first intermediate layer 1220 (for example, a portion of a 1^{st}-2 functional layer 1223) may be disposed on the upper surface of the 1^{st}-2 portion AE1-2. A portion of the first intermediate layer 1220 (for example, a 1^{st}-1 functional layer 1221 and a first emission layer 1222) may be disposed on the side surface of the 1^{st}-2 portion AE1-2. Accordingly, the 1^{st}-2 portion AE1-2 may have a shape that appears to dig into the side surface of the first intermediate layer 1220.

A thickness t2 of the first intermediate layer 1220 may be greater than a thickness t1 of the 1^{st}-2 portion AE1-2, but the disclosure is not necessarily limited thereto. In an embodiment, the thickness t2 of the first intermediate layer 1220 may be substantially equal to the thickness t1 of the 1^{st}-2 portion AE1-2, and the first intermediate layer 1220 may cover only the side surfaces of the 1^{st}-2 portion AE1-2.

It may be said that an area VIII of the embodiment illustrated in FIG. 6 is substantially the same as the embodiment illustrated in FIG. 8A. However, the disclosure is not necessarily limited thereto, and the embodiment illustrated in FIG. 8B or FIG. 8C may also be applied to the area VIII of the embodiment illustrated in FIG. 6. The structure described with reference to FIGS. 8A to 8C may be variously applied to the structure of the portion adjacent to the auxiliary electrode and the first to third intermediate layers among various embodiments.

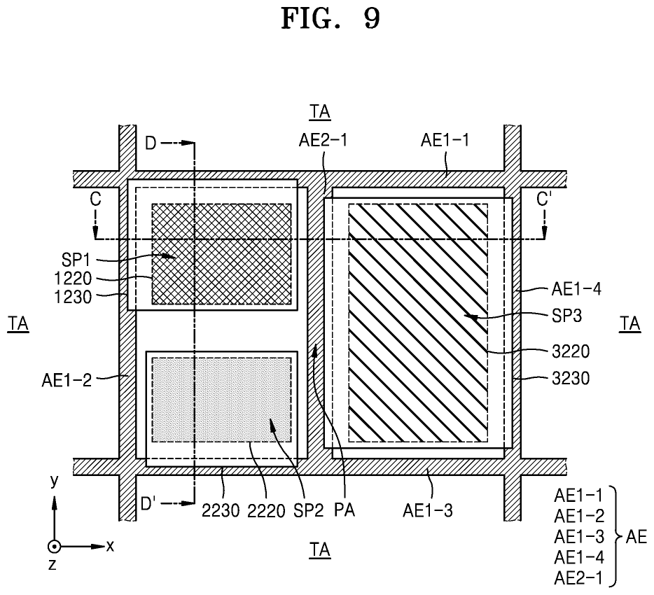

FIG. 9 is an enlarged schematic plan view illustrating a portion of a display apparatus according to an embodiment.

Referring to FIG. 9, an auxiliary electrode AE may include 1^{st}-1 to 1^{st}-4 portions AE1-1, AE1-2, AE1-3, and AE1-4 surrounding a pixel area PA, and a 2^{nd}-1 portion AE2-1 extending to the pixel area PA. For example, the auxiliary electrode AE may include the 2^{nd}-1 portion AE2-1 extending in the ±y directions and intersecting the pixel area PA vertically (or in the ±y directions).

The 2^{nd}-1 portion AE2-1 of the auxiliary electrode AE may divide the pixel area PA into areas. For example, the 2^{nd}-1 portion AE2-1 may divide the pixel area PA into a left (or −x side) area where first and second sub-pixels SP1 and SP2 are arranged and a right (or +x side) area where a third sub-pixel SP3 is arranged. By way of example, the 2^{nd}-1 portion AE2-1 of the auxiliary electrode AE may separate the first and second sub-pixels SP1 and SP2 and the third sub-pixel SP3 from each other.

The first to third opposite electrodes 1230, 2230, and 3230 may extend in one direction or in different directions and may be in contact with the auxiliary electrode AE.

The first opposite electrode 1230 may be disposed on the first intermediate layer 1220 and may extend in two different directions beyond the edge of the first intermediate layer 1220. For example, the first opposite electrode 1230 may extend in the +y direction beyond the +y side edge of the first intermediate layer 1220 and may be in contact with the 1^{st}-1 portion AE1-1 of the auxiliary electrode AE. Simultaneously, the first opposite electrode 1230 may extend in the −x direction beyond the −x side edge of the first intermediate layer 1220 and may be in contact with the 1^{st}-2 portion AE1-2 of the auxiliary electrode AE. The first opposite electrode 1230 may simultaneously overlap the 1^{st}-1 and 1^{st}-2 portions AE1-1 and AE1-2. Areas where the first opposite electrode 1230 overlaps the 1^{st}-1 and 1^{st}-2 portions AE1-1 and AE1-2 may extend in different directions. For example, the area where the first opposite electrode 1230 overlaps the 1^{st}-1 portion AE1-1 may have an elongated, substantially rectangular shape extending in the ±x directions. The area where the first opposite electrode 1230 overlaps the 1^{st}-2 portion AE1-2 may have an elongated, substantially rectangular shape extending in the ±y directions. The two areas may be connected to each other and have substantially an L-shape.

The second opposite electrode 2230 may be disposed on the second intermediate layer 2220, may extend in the −y direction beyond the −y side edge of the second intermediate layer 2220, and may be in contact with the 1st-third portion AE1-3 of the auxiliary electrode AE. The second opposite electrode 2230 may overlap the 1^{st}-3 portion AE1-3 of the auxiliary electrode AE.

The third opposite electrode 3230 may be disposed on the third intermediate layer 3220 and may extend in two different directions beyond the edge of the third intermediate layer 3220. For example, the third opposite electrode 3230 may extend in the +x direction beyond the +x side edge of the third intermediate layer 3220 and may be in contact with the 1^{st}-4 portion AE1-4 of the auxiliary electrode AE. Simultaneously, the third opposite electrode 3230 may extend in the −x direction beyond the +x side edge of the third intermediate layer 3220 and may be in contact with the 2^{nd}-1 portion AE2-1 of the auxiliary electrode AE. The third opposite electrode 3230 may simultaneously overlap the 1^{st}-4 and 2^{nd}-1 portions AE1-4 and AE2-1. The area where the third opposite electrode 3230 overlaps the 1^{st}-4 and 2^{nd}-1 portions AE1-4 and AE2-1 may have an elongated, substantially rectangular shape extending in the ±y directions. The area where the third opposite electrode 3230 overlaps the 1^{st}-4 and 2^{nd}-1 portions AE1-4 and AE2-1 may be spaced apart from each other and may be located (or disposed) on opposite sides of the third opposite electrode 3230.

Similar to the 1^{st}-1 to 1^{st}-4 portions AE1-1, AE1-2, AE1-3, and AE1-4 of the auxiliary electrode AE, a voltage may also be applied to the 2^{nd}-1 portion AE2-1. Therefore, the first opposite electrode 1230 may receive the same voltage through the 1^{st}-1 and 1^{st}-2 portions AE1-1 and AE1-2, the second opposite electrode 2230 may receive the same voltage through the 1^{st}-3 portion AE1-3, and the third opposite electrode 3230 may receive the same voltage through the 1^{st}-4 and 2^{nd}-1 portions AE1-4 and AE2-1.

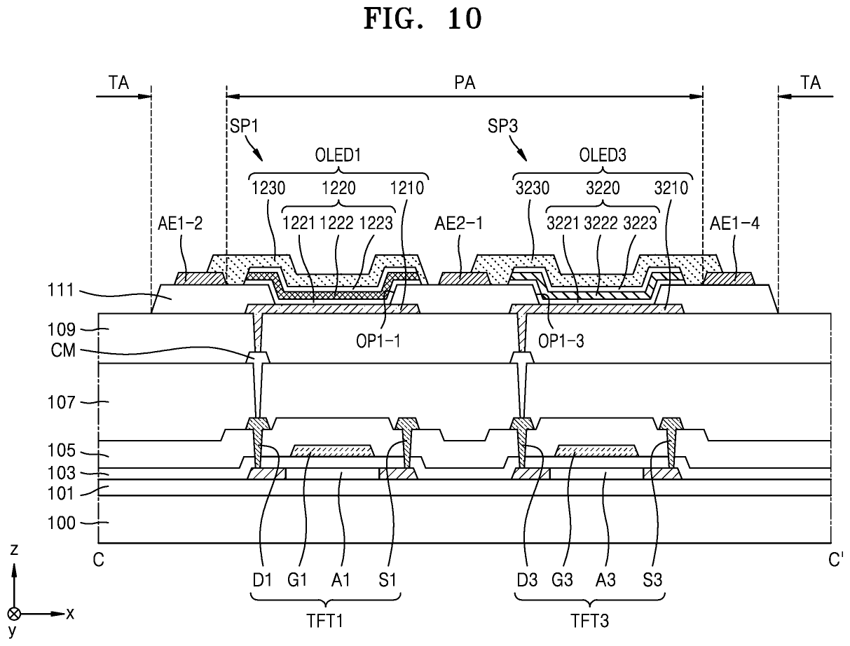

FIG. 10 is an enlarged schematic cross-sectional view illustrating a portion of a display apparatus according to an embodiment.

FIG. 10 is a schematic cross-sectional view of the embodiment of FIG. 9 taken along line C-C′ of FIG. 9.

Similar to the embodiment illustrated in FIG. 6, the first opposite electrode 1230 may cover the first intermediate layer 1220, may extend in the −x direction, and may be in contact with the 1^{st}-2 portion AE1-2.

Similar to the embodiment illustrated in FIG. 6, the third opposite electrode 3230 may cover the third intermediate layer 3220, may extend in the +x direction, and may be in contact with the 1^{st}-4 portion AE1-4.

The 2^{nd}-1 portion AE2-1 of the auxiliary electrode may be disposed on the bank layer 111 between the first and third opposite electrodes 1230 and 3230. Accordingly, it may be said that the 2^{nd}-1 portion AE2-1 is arranged in the pixel area PA.

A portion of the third opposite electrode 3230 may extend beyond the edge of the third intermediate layer 3220 and overlap the 2^{nd}-1 portion AE2-1. In an embodiment, a portion (for example, a portion on the −x side) opposite to a portion of the third opposite electrode 3230 in contact with the 1^{st}-4 portion AE1-4 may extend in the −x direction beyond the −x side edge of the third intermediate layer 3220 and overlap the 2^{nd}-1 portion AE2-1. The third opposite electrode 3230 may be in direct contact with the 2^{nd}-1 portion AE2-1.

The third opposite electrode 3230 may be simultaneously in contact with the 1^{st}-4 portion AE1-4 and the 2^{nd}-1 portion AE2-1. Accordingly, the third opposite electrode 3230 may receive a voltage through the 1^{st}-4 portion AE1-4 and the 2^{nd}-1 portion AE2-1.

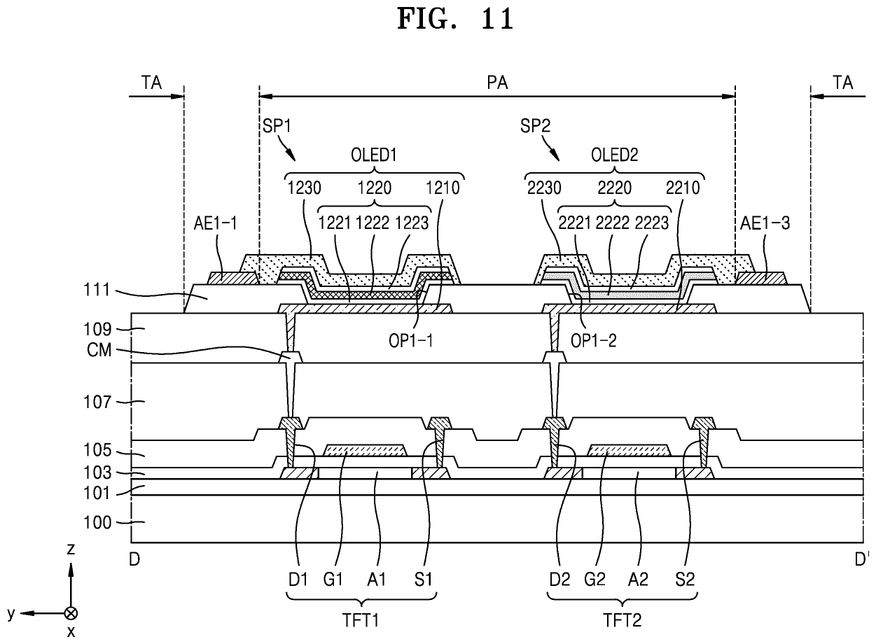

FIG. 11 is an enlarged schematic cross-sectional view illustrating a portion of a display apparatus according to an embodiment.

FIG. 11 is a schematic cross-sectional view of the embodiment of FIG. 9 taken along line D-D′ of FIG. 9.

A portion of the first opposite electrode 1230 may extend beyond the edge of the first intermediate layer 1220 and overlap the 1^{st}-1 portion AE1-1. In an embodiment, a portion of the first opposite electrode 1230 may cover the −y side edge and the side surface of the first intermediate layer 1220. On the other hand, a portion of the opposite side of the first opposite electrode 1230 may extend in the +y direction beyond the +y side edge of the first intermediate layer 1220 and overlap the 1^{st}-1 portion AE1-1. The first opposite electrode 1230 may be in direct contact with the 1^{st}-1 portion AE1-1.

The first opposite electrode 1230 may be simultaneously in contact with the 1^{st}-2 portion (see AE1-2 of FIG. 10) and the 1^{st}-1 portion AE1-1. Accordingly, the first opposite electrode 1230 may receive a voltage through the 1^{st}-2 portion (see AE1-2 of FIG. 10) and the 1^{st}-1 portion AE1-1.

Similar to the embodiment illustrated in FIG. 7, the second opposite electrode 2230 may cover the second intermediate layer 2220, may extend in the −y direction, and may be in contact with the 1^{st}-3 portion AE1-3.

FIGS. 10 and 11 illustrate that the bank layer 111 is not present in the transmission area TA. However, as described with reference to FIGS. 3A and 3B, an embodiment in which any layer from the bank layer 111 to a layer selected from the second organic insulating layer 109, the first organic insulating layer 107, the interlayer insulating layer 105, and the gate insulating layer 103 is not present in the transmission area TA may be included in the embodiments.

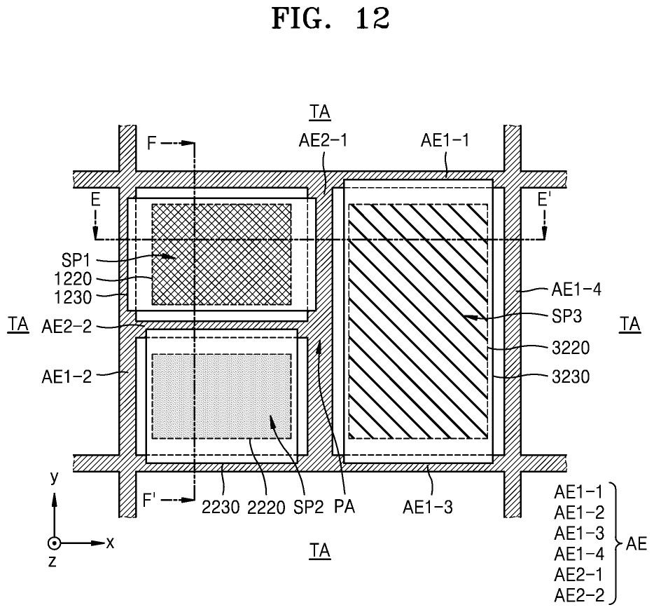

FIG. 12 is an enlarged schematic plan view illustrating a portion of a display apparatus according to an embodiment.

The remaining features except for some features of the embodiment illustrated in FIG. 12 are the same as those of the embodiment illustrated in FIG. 9, the differences will be described below.

Referring to FIG. 12, an auxiliary electrode AE may further include a 2^{nd}-2 portion AE2-2 in a pixel area PA. For example, the auxiliary electrode AE may include a 2^{nd}-2 portion AE2-2 extending in a horizontal direction (or in the ±x directions) from a 1^{st}-2 portion AE1-2 toward a 2^{nd}-1 portion AE2-1. The 2^{nd}-2 portion AE2-2 may connect the 1^{st} -2 portion AE1-2 to the 2^{nd}-1 portion AE2-1.

The 2^{nd}-2 portion AE2-2 of the auxiliary electrode AE may divide the pixel area PA into areas. For example, the 2^{nd}-2 portion AE2-2 of the auxiliary electrode AE may be between a first sub-pixel SP1 and a second sub-pixel SP2 and may separate the first sub-pixel SP1 and the second sub-pixel SP2 from each other. The 2^{nd}-1 and 2^{nd}-2 portions AE2-1 and AE2-2 may divide the pixel area PA into three areas where the first to third sub-pixels SP1, SP2, and SP3 are respectively arranged.

First to third opposite electrodes 1230, 2230, and 3230 may extend in directions and may be in contact with the auxiliary electrode AE.

The first opposite electrode 1230 may be disposed on a first intermediate layer 1220 and may extend in two different directions beyond the edge of the first intermediate layer 1220. For example, the first opposite electrode 1230 may extend in the +x direction beyond the +x side edge of the first intermediate layer 1220 and may be in contact with the 2^{nd}-1 portion AE2-1 of the auxiliary electrode AE. Simultaneously, the first opposite electrode 1230 may extend in the −x direction beyond the −x side edge of the first intermediate layer 1220 and may be in contact with the 1^{st}-2 portion AE1-2 of the auxiliary electrode AE. The first opposite electrode 1230 may simultaneously overlap the 2^{nd}-1 portion AE2-1 and the 1^{st}-2 portion AE1-2. The areas where the first opposite electrode 1230 overlaps the 2^{nd}-1 portion AE2-1 and the 1^{st}-2 portion AE1-2 may have an elongated, substantially rectangular shape extending in the ±y directions. The areas where the first opposite electrode 1230 overlaps the 2^{nd}-1 portion AE2-1 and the 1^{st}-2 portion AE1-2 may be spaced apart from each other and may be located on opposite sides of the first opposite electrode 1230.

The second opposite electrode 2230 may be disposed on a second intermediate layer 2220 and may extend in two different directions beyond the edge of the second intermediate layer 2220. For example, the second opposite electrode 2230 may extend in the +y direction beyond the +y side edge of the second intermediate layer 2220 and may be in contact with the 2^{nd}-2 portion AE2-2 of the auxiliary electrode AE. Simultaneously, the second opposite electrode 2230 may extend in the −y direction beyond the −y side edge of the second intermediate layer 2220 and may be in contact with the 1^{st}-3 portion AE1-3 of the auxiliary electrode AE. The second opposite electrode 2230 may simultaneously overlap the 2^{nd}-2 portion AE2-2 and the 1^{st}-3 portion AE1-3. The areas where the second opposite electrode 2230 overlaps the 2^{nd}-2 portion AE2-2 and the 1^{st}-3 portion AE1-3 may have an elongated, substantially rectangular shape extending in the ±x directions. The areas where the second opposite electrode 2230 overlaps the 2^{nd}-2 portion AE2-2 and the 1^{st}-3 portion AE1-3 may be spaced apart from each other and may be located on opposite sides of the second opposite electrode 2230.

The third opposite electrode 3230 may be disposed on a third intermediate layer 3220 and may extend in two different directions beyond the edge of the third intermediate layer 3220. For example, the third opposite electrode 3230 may extend in the +y direction beyond the +y side edge of the third intermediate layer 3220 and may be in contact with the 1^{st}-1 portion AE1-1 of the auxiliary electrode AE. Simultaneously, the third opposite electrode 3230 may extend in the −y direction beyond the −y side edge of the third intermediate layer 3220 and may be in contact with the 1^{st}-3 portion AE1-3 of the auxiliary electrode AE. The third opposite electrode 3230 may simultaneously overlap the 1^{st}-1 portion AE1-1 and the 1^{st}-3 portion AE1-3. The areas where the third opposite electrode 3230 overlaps the 1^{st}-1 portion AE1-1 and the 1^{st}-3 portion AE1-3 may have an elongated, substantially rectangular shape extending in the ±x directions. The area where the third opposite electrode 3230 overlaps the 1^{st}-1 and 1^{st}-3 portions AE1-1 and AE1-3 may be spaced apart from each other and may be located on opposite sides of the third opposite electrode 3230.

Similar to the 1^{st}-1 to 1^{st}-4 portions AE1-1, AE1-2, AE1-3, and AE1-4 and the 2^{nd}-1 portion AE2-1 of the auxiliary electrode AE, a voltage may also be applied to the 2^{nd}-2 portion AE2-2. Therefore, the first opposite electrode 1230 may receive the same voltage through the 2^{nd}-1 and 1^{st}-2 portions AE2-1 and AE1-2, the second opposite electrode 2230 may receive the same voltage through the 2^{nd}-2 and 1^{st}-3 portions AE2-2 and AE1-3, and the third opposite electrode 3230 may receive the same voltage through the 1^{st}-1 and 1^{st}-3 portions AE1-1 and AE1-3.

FIG. 13 is an enlarged schematic cross-sectional view illustrating a portion of a display apparatus according to an embodiment.

FIG. 13 is a schematic cross-sectional view of the embodiment of FIG. 12 taken along line E-E′ of FIG. 12.

A portion of a first opposite electrode 1230 may extend beyond an edge of a first intermediate layer 1220. For example, a portion of the first opposite electrode 1230 may extend in the +x direction beyond the +x side edge of the first intermediate layer 1220 and overlap a 2^{nd}-1 portion AE2-1. The first opposite electrode 1230 may be in direct contact with the 2^{nd}-1 portion AE2-1. A portion of the opposite side of the first opposite electrode 1230 may extend in the −x direction beyond the −x side edge of the first intermediate layer 1220 and overlap a 1^{st}-2 portion AE1-2. The first opposite electrode 1230 may be in direct contact with the 1^{st}-2 portion AE1-2.

The first opposite electrode 1230 may be simultaneously in contact with the 2^{nd}-1 portion AE2-1 and the 1^{st}-2 portion AE1-2. Accordingly, the first opposite electrode 1230 may receive a voltage through the 2^{nd}-1 portion AE2-1 and the 1^{st}-2 portion AE1-2.

The third opposite electrode 3230 may be disposed on the bank and cover an ±x side edge of a third intermediate layer 3220.

FIG. 14 is an enlarged schematic plan view illustrating a portion of a display apparatus according to an embodiment.

FIG. 14 is a schematic cross-sectional view of the embodiment of FIG. 12 taken along line F-F′ of FIG. 12.

A first opposite electrode 1230 may be disposed on a bank layer 111 and cover an ±y side edge of a first intermediate layer 1220.

A 2^{nd}-2 portion AE2-2 of an auxiliary electrode may be disposed on the bank layer 111 between the first opposite electrode 1230 and a second opposite electrode 2230. Accordingly, it may be said that the 2^{nd}-2 portion AE2-2 is arranged in a pixel area PA.

A portion of the second opposite electrode 2230 may extend beyond an edge of a second intermediate layer 2220. For example, a portion of the second opposite electrode 2230 may extend in the +y direction beyond the +y side edge of the second intermediate layer 2220 and overlap the 2^{nd}-2 portion AE2-2. The second opposite electrode 2230 may be in direct contact with the 2^{nd}-2 portion AE2-2. A portion of the opposite side of the second opposite electrode 2230 may extend in the −y direction beyond the −y side edge of the second intermediate layer 2220 and overlap a 1^{st}-3 portion AE1-3. The second opposite electrode 2230 may be in direct contact with the 1^{st}-3 portion AE1-3.

The second opposite electrode 2230 may be simultaneously in contact with the 2^{nd}-2 portion AE2-2 and the 1^{st}-3 portion AE1-3. Accordingly, the second opposite electrode 2230 may receive a voltage through the 2^{nd}-2 portion AE2-2 and the 1^{st}-3 portion AE1-3.

FIGS. 13 and 14 illustrate that the bank layer 111 is not present in the transmission area TA. However, as described with reference to FIGS. 3A and 3B, an embodiment in which a layer from the bank layer 111 to any layer selected from the second organic insulating layer 109, the first organic insulating layer 107, the interlayer insulating layer 105, and the gate insulating layer 103 is not present in the transmission area TA may be included in the embodiments.

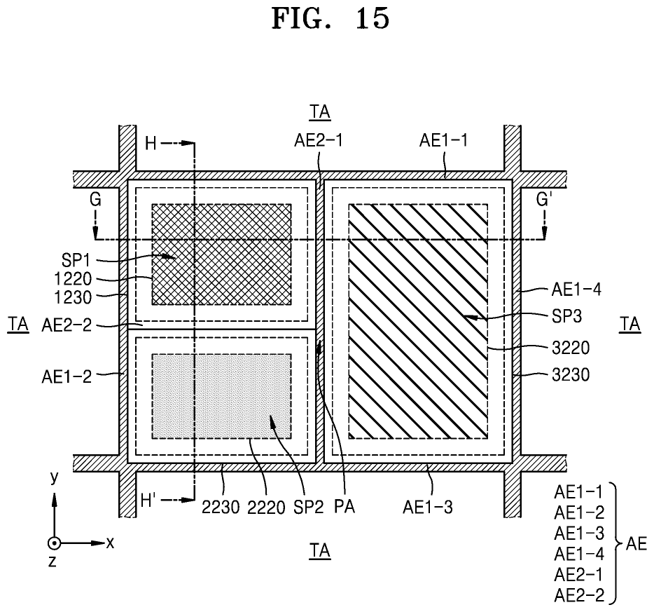

FIG. 15 is an enlarged schematic plan view illustrating a portion of a display apparatus according to an embodiment.

The remaining features except for some features of the embodiment illustrated in FIG. 15 are the same as those of the embodiment illustrated in FIG. 12, the differences will be described below.

First to third opposite electrodes 1230, 2230, and 3230 may extend in different directions and may be in contact with an auxiliary electrode AE.

The first opposite electrode 1230 may be disposed on a first intermediate layer 1220 and may extend in four different directions beyond the edge of the first intermediate layer 1220. For example, the first opposite electrode 1230 may extend in the ±x directions beyond the ±x side edge of the first intermediate layer 1220 and may be in contact with a 2^{nd}-1 portion AE2-1 and a 1^{st}-2 portion AE1-2 of the auxiliary electrode AE. The first opposite electrode 1230 may simultaneously overlap the 2^{nd}-1 portion AE2-1 and the 1^{st}-2 portion AE1-2. Simultaneously, the first opposite electrode 1230 may extend in the ±y directions beyond the ±y side edge of the first intermediate layer 1220 and may be in contact with a 1^{st}-1 portion AE1-1 and a 2^{nd}-2 portion AE2-2. The first opposite electrode 1230 may simultaneously overlap the 1^{st}-1 portion AE1-1 and the 2^{nd}-2 portion AE2-2.

Areas where the first opposite electrode 1230 overlaps the 1^{st}-1 portion AE1-1, the 1^{st}-2 portion AE1-2, the 2^{nd}-1 portion AE2-1, and the 2^{nd}-2 portion AE2-2 may be connected to each other. Accordingly, the shape of the area where the first opposite electrode 1230 overlaps the auxiliary electrode AE may have substantially a frame shape surrounding the first intermediate layer 1220.

The second opposite electrode 2230 may be disposed on a second intermediate layer 2220 and may extend in four different directions beyond the edge of the second intermediate layer 2220. For example, the second opposite electrode 2230 may extend in the ±x directions beyond the ±x side edge of the second intermediate layer 2220 and may be in contact with the 2^{nd}-1 portion AE2-1 and the 1^{st}-2 portion AE1-2 of the auxiliary electrode AE. The second opposite electrode 2230 may simultaneously overlap the 2^{nd}-1 portion AE2-1 and the 1^{st}-2 portion AE1-2. Simultaneously, the second opposite electrode 2230 may extend in the ±y directions beyond the ±y side edge of the second intermediate layer 2220 and may be in contact with the 2^{nd}-2 portion AE2-2 and a 1^{st}-3 portion AE1-3. The second opposite electrode 2230 may simultaneously overlap the 2^{nd}-2 portion AE2-2 and the 1^{st}-3 portion AE1-3.

Areas where the second opposite electrode 2230 overlaps the 1^{st}-2 portion AE1-2, the 1^{st}-3 portion AE1-3, the 2^{nd}-1 portion AE2-1, and the 2^{nd}-2 portion AE2-2 may be connected to each other. Accordingly, the shape of the area where the second opposite electrode 2230 overlaps the auxiliary electrode AE may have substantially a frame shape surrounding the second intermediate layer 2220.

The third opposite electrode 3230 may be disposed on a third intermediate layer 3220 and may extend in four different directions beyond the edge of the third intermediate layer 3220. For example, the third opposite electrode 3230 may extend in the ±x directions beyond the ±x side edge of the third intermediate layer 3220 and may be in contact with a 1^{st}-4 portion AE1-4 and the 2^{nd}-1 portion AE2-1 of the auxiliary electrode AE. The third opposite electrode 3230 may simultaneously overlap the 1^{st}-4 portion AE1-4 and the 2^{nd}-1 portion AE2-1. Simultaneously, the third opposite electrode 3230 may extend in the ±y directions beyond the ±y side edge of the third intermediate layer 3220 and may be in contact with the 1^{st}-1 portion AE1-1 and the 1^{st}-3 portion AE1-3. The third opposite electrode 3230 may simultaneously overlap the 1^{st}-1 portion AE1-1 and the 1^{st}-3 portion AE1-3.

Areas where the third opposite electrode 3230 overlaps the 1^{st}-1 portion AE1-1, the 1^{st}-3 portion AE1-3, the 1^{st}-4 portion AE1-4, and the 2^{nd}-1 portion AE2-1 may be connected to each other. Accordingly, the shape of the area where the third opposite electrode 3230 overlaps the auxiliary electrode AE may have substantially a frame shape surrounding the third intermediate layer 3220.

The first opposite electrode 1230 may be in contact with the second opposite electrode 2230. For example, the first opposite electrode 1230 and the second opposite electrode 2230 may be in contact with each other on the 2^{nd}-2 portion AE2-2 of the auxiliary electrode AE.

Both the first opposite electrode 1230 and the third opposite electrode 3230 may be in contact with the 2^{nd}-1 portion AE2-1 of the auxiliary electrode AE and may be spaced apart from each other on the 2^{nd}-1 portion AE2-1. In other words, an area of the 2^{nd}-1 portion AE2-1 that does not overlap the first and third opposite electrodes 1230 and 3230 may be between the first opposite electrode 1230 and the third opposite electrode 3230.

Both the second opposite electrode 2230 and the third opposite electrode 3230 may be in contact with the 2^{nd}-1 portion AE2-1 of the auxiliary electrode AE and may be spaced apart from each other on the 2^{nd}-1 portion AE2-1. In other words, an area of the 2^{nd}-1 portion AE2-1 that does not overlap the second and third opposite electrodes 2230 and 3230 may be between the second opposite electrode 2230 and the third opposite electrode 3230.

Of course, the disclosure is not limited thereto. In an embodiment, the first opposite electrode 1230 and the second opposite electrode 2230 may be spaced apart from each other on the 2^{nd}-2 portion AE2-2 of the auxiliary electrode AE. In an embodiment, the first opposite electrode 1230 and the third opposite electrode 3230 may be in contact with each other on the 2^{nd}-1 portion AE2-1 of the auxiliary electrode AE. In an embodiment, the second opposite electrode 2230 and the third opposite electrode 3230 may be in contact with each other on the 2^{nd}-1 portion AE2-1 of the auxiliary electrode AE.

The first opposite electrode 1230 may receive a voltage through the 1^{st}-1 portion AE1-1, the 1^{st}-2 portion AE1-2, the 2^{nd}-1 portion AE2-1, and the 2^{nd}-2 portion AE2-2 of the auxiliary electrode AE. The second opposite electrode 2230 may receive the same voltage through the 1^{st}-2 portion AE1-2, the 1^{st}-3 portion AE1-3, the 2^{nd}-1 portion AE2-1, and the 2^{nd}-2 portion AE2-2 of the auxiliary electrode AE. The third opposite electrode 3230 may receive the same voltage through the 1^{st}-1 portion AE1-1, the 1^{st}-3 portion AE1-3, the 1^{st}-4 portion AE1-4, and the 2^{nd}-1 portion AE2-1 of the auxiliary electrode AE.

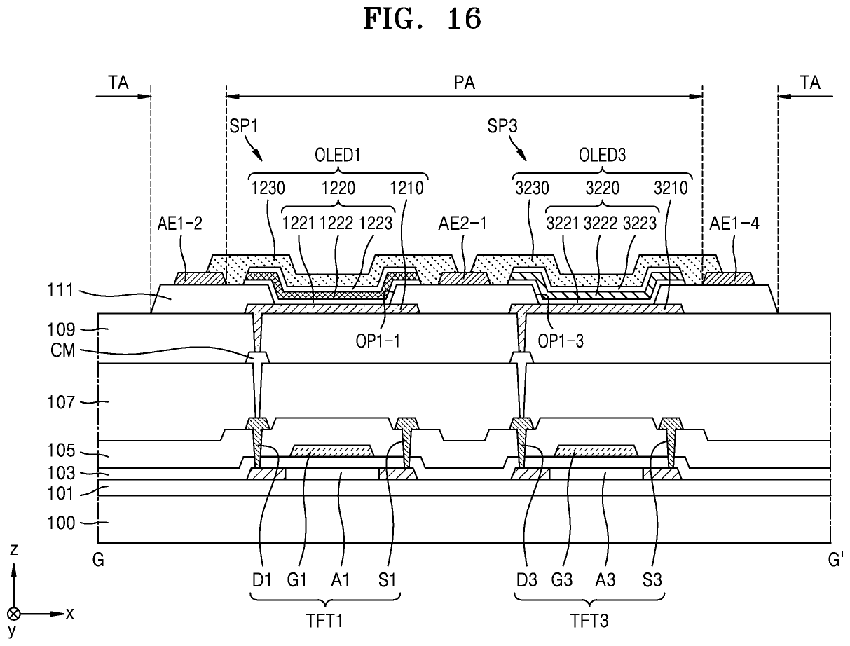

FIG. 16 is an enlarged schematic cross-sectional view illustrating a portion of a display apparatus according to an embodiment.

FIG. 16 is a schematic cross-sectional view of the embodiment of FIG. 15 taken along line G-G′ of FIG. 15.

Similar to the embodiment illustrated in FIG. 13, the first opposite electrode 1230 may cover the first intermediate layer 1220, may extend in the ±x directions, and may be in contact with the 2^{nd}-1 portion AE2-1 and the 1^{st}-2 portion AE1-2.

Similar to the embodiment illustrated in FIG. 10, the third opposite electrode 3230 may cover the third intermediate layer 3220, may extend in the ±x directions, and may be in contact with the 1^{st}-4 portion AE1-4 and the 2^{nd}-1 portion AE2-1.

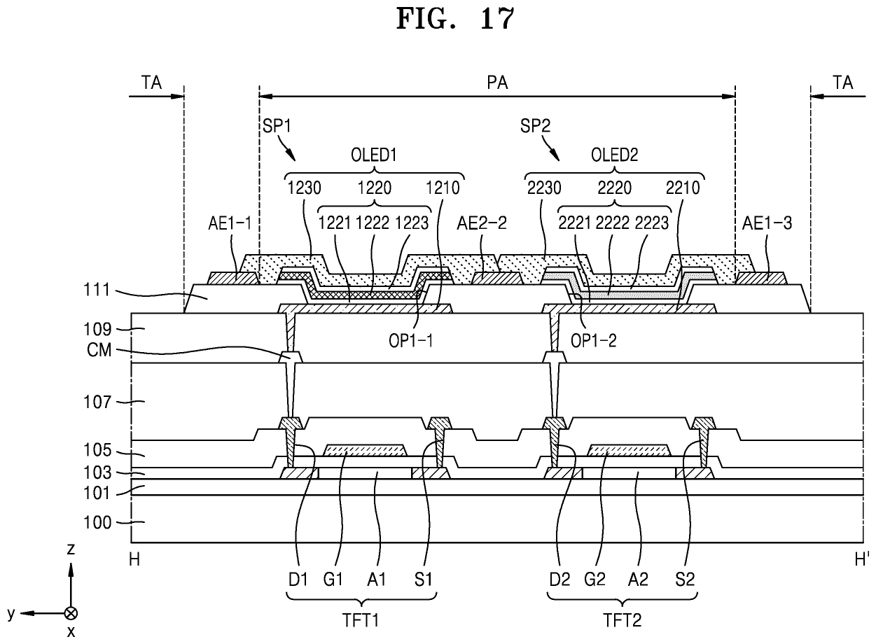

FIG. 17 is an enlarged schematic cross-sectional view illustrating a portion of a display apparatus according to an embodiment.

FIG. 17 is a schematic cross-sectional view of the embodiment of FIG. 15 taken along line H-H′ of FIG. 15.

A portion of the first opposite electrode 1230 may extend beyond the edge of the first intermediate layer 1220. For example, a portion of the first opposite electrode 1230 may extend in the +y direction beyond the +y side edge of the first intermediate layer 1220 and overlap the 1^{st}-1 portion AE1-1. The first opposite electrode 1230 may be in direct contact with the 1^{st}-1 portion AE1-1. A portion of the opposite side of the first opposite electrode 1230 may extend in the −y direction beyond the −y side edge of the first intermediate layer 1220 and overlap the 2^{nd}-2 portion AE2-2. The first opposite electrode 1230 may be in direct contact with the 2^{nd}-2 portion AE2-2.

Similar to the embodiment illustrated in FIG. 14, the second opposite electrode 2230 may cover the second intermediate layer 2220, may extend in the ±y direction, and may be in contact with the 2^{nd}-2 portion AE2-2 and the 1^{st}-3 portion AE1-3.

The first opposite electrode 1230 and the second opposite electrode 2230 may be in contact with each other on the 2^{nd}-2 portion AE2-2. A portion of the first opposite electrode 1230 may be in contact with a portion of the second opposite electrode 2230. For example, a portion of the second opposite electrode 2230 may be arranged on the side surface of the first opposite electrode 1230. This is characteristics due to the manufacturing process and is a structure that may occur in case that the first intermediate layer 1220 and the first opposite electrode 1230 are formed prior to the second intermediate layer 2220 and the second opposite electrode 2230. In an embodiment, in case that the second opposite electrode 2230 is formed prior to the first opposite electrode 1230, a portion of the first opposite electrode 1230 may be arranged on the side surface of the second opposite electrode 2230.

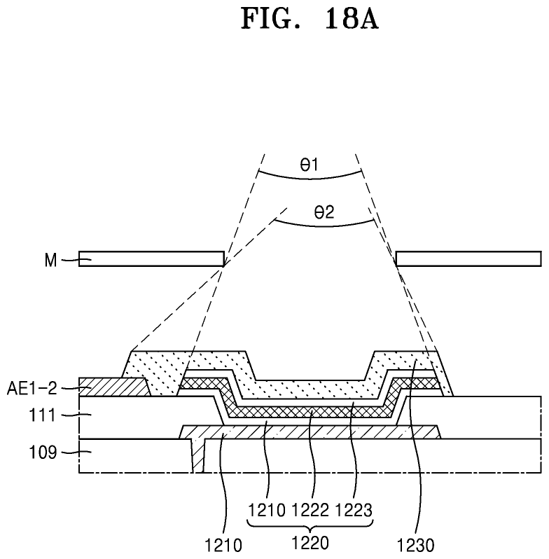

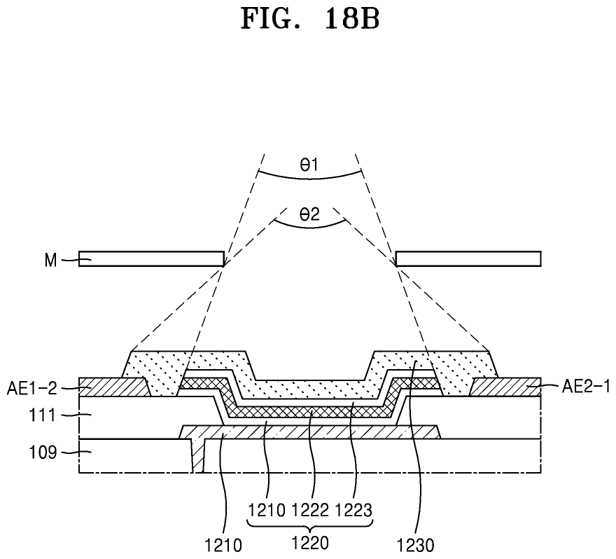

FIGS. 18A and 18B are schematic cross-sectional views schematically illustrating states of a display apparatus manufacturing process according to various embodiments.

In FIGS. 18A and 18B, a first intermediate layer 1220 and a first opposite electrode 1230 may be deposited on a first sub-pixel electrode 1210 and a bank layer 111. The first intermediate layer 1220 and the first opposite electrode 1230 may be deposited by using the same mask M. In order to deposit different areas by using the same mask M, a process of depositing the first intermediate layer 1220 and a process of depositing the first opposite electrode 1230 may be performed at different angles or by using different methods.

FIG. 18A may be a schematic cross-sectional view illustrating a state according to a process of depositing the first intermediate layer 1220 and the first opposite electrode 1230 in the embodiment illustrated in FIG. 6.

Referring to FIG. 18A, the first intermediate layer 1220 may be sprayed at a first deposition angle θ1 and deposited on the first sub-pixel electrode 1210 and the bank layer 111.

In case that the first intermediate layer 1220 is deposited, a 1^{st}-1 functional layer 1221, a first emission layer 1222, and a 1^{st}-2 functional layer 1223 may be sequentially deposited in this stated order.

Thereafter, the first opposite electrode 1230 may be deposited to be in contact with a 1^{st}-2 portion AE1-2 beyond the edge of the first intermediate layer 1220 while covering the first intermediate layer 1220. The process of depositing the first opposite electrode 1230 may include oblique deposition. For example, by spraying a deposition material at a second deposition angle θ2 that is oblique to the first deposition angle θ1 and has a different magnitude from the first deposition angle θ1, the first opposite electrode 1230 may be formed to extend beyond one edge of the first intermediate layer 1220 while covering the first intermediate layer 1220. At this time, the position and magnitude of the second deposition angle θ2 may be appropriately adjusted so that a portion of the first opposite electrode 1230 is in contact with the 1^{st}-2 portion AE1-2.

FIG. 18B may be a schematic cross-sectional view illustrating a state according to a process of depositing the first intermediate layer 1220 and the first opposite electrode 1230 in the embodiment illustrated in FIG. 16.

Referring to FIG. 18B, as in the case of FIG. 18A, the first intermediate layer 1220 may be sprayed at a first deposition angle θ1 and deposited on the first sub-pixel electrode 1210 and the bank layer 111.

Thereafter, the first opposite electrode 1230 may be deposited to be in contact with a 1^{st}-2 portion AE1-2 and the 2^{nd}-1 portion AE2-1 beyond the edge of the first intermediate layer 1220 while covering the first intermediate layer 1220. The depositing of the first opposite electrode 1230 may be performed by, for example, spraying a deposition material at a second deposition angle θ2 that is greater than the first deposition angle θ1. By way of example, the depositing of the first opposite electrode 1230 may be performed by sputtering.

Through the manufacturing process according to the embodiment illustrated in FIGS. 18A and 18B, the first opposite electrode 1230 may be formed by using the same mask as the first intermediate layer 1220 without the need to use a separate mask. The first opposite electrode 1230 may be formed while varying the area. In case that the position and magnitude of the second deposition angle θ2 are appropriately adjusted, the extension of the first opposite electrode 1230 beyond the edge of the first intermediate layer 1220 may be implemented as extension in a single direction (for example, the −x direction) illustrated in FIG. 5, extension in two intersecting directions (for example, the −x direction and the +y direction) illustrated in FIG. 9, extension in both directions (for example, the ±x directions) illustrated in FIG. 12, or extension in four directions (for example, the ±x directions and the ±y directions) illustrated in FIG. 15.

In FIGS. 18A and 18B, the description has been given based on the first opposite electrode 1230 and the first intermediate layer 1220, but the deposition method of the disclosure may be equally applied to the second and third opposite electrodes and the second and third intermediate layers.

According to the embodiment described above, the metal layer (for example, the opposite electrode), which is the main cause of the decrease in transmittance, does not overlap the transmittance area, and thus, the transmittance of the transmittance area may increase. The opposite electrodes separated from each other in the pixel area may receive a common voltage through the auxiliary electrode. Because the auxiliary electrode also does not overlap the transmission area, the transmittance of the transmission area may not be reduced.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure and as defined by the following claims.

What is claimed is:

1. A display apparatus comprising:
a pixel area and an adjacent transmission area;
a first sub-pixel electrode, a second sub-pixel electrode, and a third sub-pixel electrode disposed on a substrate, disposed in a pixel area, and spaced apart from each other;
a bank layer overlapping an edge of each of the first sub-pixel electrode, the second sub-pixel electrode, and the third sub-pixel electrode;
a first intermediate layer, a second intermediate layer, and a third intermediate layer respectively disposed on the first sub-pixel electrode, the second sub-pixel electrode, and the third sub-pixel electrode and spaced apart from each other;
a first opposite electrode, a second opposite electrode, and a third opposite electrode respectively disposed on the first intermediate layer, the second intermediate layer, and the third intermediate layer and spaced apart from each other; and
an auxiliary electrode disposed on the bank layer,
wherein the first opposite electrode, the second opposite electrode, and the third opposite electrode respectively pass through edges of the first intermediate layer, the second intermediate layer, and the third intermediate layer and electrically contact the auxiliary electrode.

2. The display apparatus of claim 1, wherein the auxiliary electrode surrounds the pixel area and the transmission area in a plan view.

3. The display apparatus of claim 1, wherein the auxiliary electrode is adjacent to the pixel area and the transmission area and extends in a direction in a plan view.

4. The display apparatus of claim 1, wherein the auxiliary electrode comprises a first portion surrounding the pixel area in a plan view.

5. The display apparatus of claim 4, wherein the first opposite electrode passes through the edge of the first intermediate layer in a direction and electrically contacts the auxiliary electrode.

6. The display apparatus of claim 4, wherein a contact area of the first opposite electrode with the auxiliary electrode, a contact area of the second opposite electrode with the auxiliary electrode, and a contact area of the third opposite electrode with the auxiliary electrode are different from each other.

7. The display apparatus of claim 4, wherein
the auxiliary electrode further comprises a second portion that is connected to the first portion, extending to the pixel area, and disposed between two of the first intermediate layer, the second intermediate layer, and the third intermediate layer, and
at least one of the first opposite electrode, the second opposite electrode, and the third opposite electrode contacts the second portion of the auxiliary electrode.

8. The display apparatus of claim 7, wherein
the first opposite electrode comprises a first portion and a second portion each overlapping the auxiliary electrode, and
the first portion of the first opposite electrode and the second portion of the first opposite electrode extend in different directions.

9. The display apparatus of claim 7, wherein
the first opposite electrode comprises a first portion and a second portion each overlapping the auxiliary electrode, and
the first portion of the first opposite electrode and the second portion of the first opposite electrode are disposed on opposite sides of the first opposite electrode.

10. The display apparatus of claim 7, wherein
the first opposite electrode and the second opposite electrode contact the second portion of the auxiliary electrode, and
the first opposite electrode and the second opposite electrode contact each other on the second portion of the auxiliary electrode.

11. The display apparatus of claim 1, further comprising:
an insulating layer disposed between the substrate and the bank layer; and
an encapsulation layer covering the opposite electrode and the auxiliary electrode,
wherein the insulating layer and the encapsulation layer directly contact the transmission area.

12. The display apparatus of claim 1, wherein an area of each of the first opposite electrode, the second opposite electrode, and the third opposite electrode is greater than an area of each of the first intermediate layer, the second intermediate layer, and the third intermediate layer.

13. A display apparatus comprising:
an auxiliary electrode disposed on a substrate and dividing the substrate into a plurality of pixel areas and a plurality of transmission areas; and
a plurality of pixels disposed on the substrate corresponding to the plurality of pixel areas, respectively, wherein
a first pixel among the plurality of pixels comprises:
a first sub-pixel electrode, a second sub-pixel electrode, and a third sub-pixel electrode disposed in a first pixel area corresponding to the first pixel and spaced apart from each other;
a first intermediate layer, a second intermediate layer, and a third intermediate layer respectively disposed on the first sub-pixel electrode, the second sub-pixel electrode, and the third sub-pixel electrode disposed and spaced apart from each other; and
a first opposite electrode, a second opposite electrode, and a third opposite electrode respectively disposed on the first intermediate layer, the second intermediate layer, and the third intermediate layer and spaced apart from each other,
the first opposite electrode, the second opposite electrode, and the third opposite electrode respectively pass through edges of the first intermediate layer, the second intermediate layer, and the third intermediate layer and contact the auxiliary electrode, and
the first opposite electrode, the second opposite electrode, and the third opposite electrode are respectively spaced apart from the plurality of transmission areas.

14. The display apparatus of claim 13, wherein the auxiliary electrode has a substantially net structure surrounding each of the plurality of pixel areas and each of the plurality of transmission areas.

15. The display apparatus of claim 14, wherein a portion of the auxiliary electrode extends to the first pixel area and is disposed in an area between the first sub-pixel electrode, the second sub-pixel electrode, and the third sub-pixel electrode disposed.

16. The display apparatus of claim 15, wherein at least one of the first opposite electrode, the second opposite electrode, and the third opposite electrode passes through an edge of a corresponding one of the first intermediate layer, the second intermediate layer, and the third intermediate layer in two or more different directions and contacts the auxiliary electrode.

17. The display apparatus of claim 15, wherein
an area of the first opposite electrode is greater than an area of the first intermediate layer, and
the first opposite electrode directly contacts the portion of the auxiliary electrode extending to the first pixel area.

18. The display apparatus of claim 13, further comprising:
an insulating layer disposed between the substrate and the first sub-pixel electrode, the second sub-pixel electrode, and the third sub-pixel electrode; and
an encapsulation layer covering the first opposite electrode, the second opposite electrode, and the third opposite electrode,
wherein the insulating layer and the encapsulation layer directly contact with each other in the plurality of transmission areas.

19. The display apparatus of claim 13, wherein a layer including a same material as a material of the first sub-pixel electrode, the second sub-pixel electrode, and the third sub-pixel electrode and the first opposite electrode, the second opposite electrode, and the third opposite electrode is not present in at least one of the plurality of transmission areas.

20. The display apparatus of claim 13, wherein
a second pixel adjacent to the first pixel comprises:
a first sub-pixel electrode, a second sub-pixel electrode, and a third sub-pixel electrode disposed in a second pixel area corresponding to the second pixel and spaced apart from each other;
a first intermediate layer, a second intermediate layer, and a third intermediate layer respectively disposed on the first sub-pixel electrode, the second sub-pixel electrode, and the third sub-pixel electrode disposed in the second pixel area and spaced apart from each other; and
a first opposite electrode, a second opposite electrode, and a third opposite electrode respectively disposed on the first intermediate layer, the second intermediate layer, and the third intermediate layer disposed in the second pixel area and spaced apart from each other, and
the first opposite electrode, the second opposite electrode, and the third opposite electrode corresponding to the second pixel area are spaced apart from the first opposite electrode, the second opposite electrode, and the third opposite electrode corresponding to the first pixel area with the transmission area disposed between.
